(19) United States
(12) Patent Application Publication
(10) Pub. No.: US 2024/0387783 A1
(43) Pub. Date: Nov. 21, 2024

(54) DISPLAY DEVICE AND METHOD FOR MANUFACTURING THE SAME

(71) Applicant: Samsung Display Co., LTD., Yongin-si (KR)

(72) Inventors: Sae Hee HAN, Yongin-si (KR); Gwui Hyun PARK, Yongin-si (KR)

(73) Assignee: Samsung Display Co., LTD., Yongin-si (KR)

(21) Appl. No.: 18/419,575

(22) Filed: Jan. 23, 2024

(30) Foreign Application Priority Data
May 17, 2023 (KR) 10-2023-0063709

(51) Int. Cl. H01L 33/48; H01L 25/16; H01L 33/62

(52) U.S. Cl. CPC H01L 33/483; H01L 25/167; H01L 33/62; H01L 2933/0066

(57) ABSTRACT

A display device comprises a via layer disposed on a substrate, a first electrode and a second electrode disposed on the via layer, a bank layer disposed on the first electrode and the second electrode, light emitting elements disposed on the bank layer, an insulating layer disposed on the light emitting elements, and a first connection electrode and a second connection electrode disposed on the bank layer and the light emitting elements, wherein the bank layer includes an element portion overlapping the light emitting element, a partition portion surrounding the element portion, and a bank portion surrounding the partition portion, and the bank layer includes fluorine, and an atomic ratio of fluorine on a surface of the bank portion is 11% or more.

### CROSS-REFERENCE TO RELATED APPLICATION

This application claims priority to and benefits of Korean Patent Application No. 10-2023-0063709 under 35 U.S.C. § 119, filed on May 17, 2023 in the Korean Intellectual Property Office (KIPO), the contents of which its entirety are incorporated herein by reference.

### BACKGROUND

### 1. Technical Field

The disclosure relates to a display device and a method for manufacturing the same.

### 2. Description of the Related Art

The importance of a display device is increasing with the development of multimedia. Accordingly, various types of display devices such as an organic light emitting display (OLED) and a liquid crystal display (LCD) are being used.

There is a self-light emitting display device including a light emitting element as a device for displaying an image of the display device. The self-light emitting display device includes an organic light emitting display device using an organic material, which is a light emitting element, as a light emitting material, or an inorganic light emitting display device using an inorganic material as a light emitting material.

### SUMMARY

Aspects of the disclosure provide a display device capable of reducing a mask process by forming a bank layer having liquid repellency and a lyophilic property, and a method for manufacturing the same.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, a display device comprises a via layer disposed on a substrate, a first electrode and a second electrode disposed on the via layer and spaced apart from each other, a bank layer disposed on the first electrode and the second electrode, light emitting elements disposed on the bank layer, an insulating layer disposed on the light emitting elements, and a first connection electrode and a second connection electrode spaced apart from each other on the bank layer and the light emitting elements, the first connection electrode being electrically connected to one end of the light emitting elements and the second connection electrode being electrically connected to another end of the light emitting elements, wherein the bank layer includes an element portion overlapping the light emitting element, a partition portion surrounding the element portion, and a bank portion surrounding the partition portion, and the bank layer includes fluorine, and an atomic ratio of fluorine on a surface of the bank portion is about 11% or more.

In an embodiment, the bank portion, the partition portion, and the element portion of the bank layer may have different thicknesses.

In an embodiment, a thickness of the bank portion may be greater than a thickness of the partition portion and a thickness of the element portion.

In an embodiment, the thickness of the partition portion may be greater than the thickness of the element portion.

In an embodiment, a thickness of the partition portion may be about 1.475 μm or more.

In an embodiment, a thickness of the partition portion and a thickness of the element portion may be about 1.438 μm or less.

In an embodiment, the atomic ratio of fluorine on the surface of the bank portion may be greater than an atomic ratio of fluorine on a surface of the partition portion and an atomic ratio of fluorine on a surface of the element portion.

In an embodiment, the atomic ratio of fluorine on the surface of the bank portion may be greater than an atomic ratio of fluorine at a center of the bank portion in a thickness direction.

In an embodiment, the bank portion, the partition portion, and the element portion of the bank layer may be integral with each other.

According to an aspect of the disclosure, a display device comprises a via layer disposed on a substrate, a first electrode and a second electrode disposed on the via layer and spaced apart from each other, a bank layer disposed on the first electrode and the second electrode, light emitting elements disposed on the bank layer, an insulating layer disposed on the light emitting elements, and a first connection electrode and a second connection electrode spaced apart from each other on the bank layer and the light emitting elements, the first connection electrode being electrically connected to one end of the light emitting elements and the second connection electrode being electrically connected to another end of the light emitting elements, wherein the bank layer includes an element portion overlapping the light emitting element, a partition portion surrounding the element portion, and a bank portion surrounding the partition portion, and the bank layer includes fluorine, and an atomic ratio of fluorine on a surface of each of the partition portion and the element portion is about 9.1% or less.

In an embodiment, a thickness of the partition portion may be about 1.475 μm or more.

In an embodiment, a thickness of the partition portion and a thickness of the element portion may be about 1.438 μm or less.

In an embodiment, an atomic ratio of fluorine on a surface of the bank portion may be greater than the atomic ratio of fluorine on the surface of the partition portion and the atomic ratio of fluorine on the surface of the element portion.

In an embodiment, an atomic ratio of fluorine on a surface of the bank portion may be greater than an atomic ratio of fluorine at a center of the bank portion in a thickness direction.

According to an aspect of the disclosure, a method for manufacturing a display device, the method comprises forming a via layer on a substrate, forming a first electrode and a second electrode spaced apart from each other on the via layer, forming a bank layer including a bank portion, a partition portion, and an element portion having different thicknesses by applying a bank material layer on the first electrode and the second electrode and using a mask, forming light emitting elements on the element portion of the bank layer, forming an insulating layer on the light emitting elements, and forming a first connection electrode and a second connection electrode spaced apart from each other on the light emitting elements, the first connection electrode being electrically connected to one end of the light emitting elements and the second connection electrode being electrically connected to another end of the light emitting elements.

In an embodiment, the bank material layer may include polyimide, a fluorine-based liquid repellent additive, and a photoactive compound.

In an embodiment, the mask may include a blocking area, a first semi-transmissive area, and a second semi-transmissive area through which a greater amount of light is transmitted than the first semi-transmissive area.

In an embodiment, the bank material layer corresponding to the blocking area may be formed as the bank portion, the bank material layer corresponding to the first semi-transmissive area may be formed as the partition portion, and the bank material layer corresponding to the second semi-transmissive area may be formed as the element portion.

In an embodiment, the forming of the bank layer may include collecting a fluorine component included in the bank material layer toward a surface by performing a soft bake process on the bank material layer, performing an exposure process on the bank material layer through the mask, developing the bank material layer, and curing the bank material layer.

In an embodiment, an atomic ratio of fluorine on a surface of the bank portion may be greater than an atomic ratio of fluorine on a surface of the partition portion and an atomic ratio of fluorine on a surface of the element portion.

In an embodiment, an atomic ratio of fluorine on a surface of the bank portion may be greater than an atomic ratio of fluorine at a center of the bank portion in a thickness direction.

In an embodiment, the thickness of the bank portion may be greater than the thickness of the partition portion, and the thickness of the partition portion may be greater than the thickness of the element portion.

In an embodiment, the thickness of the partition portion may be formed to be about 1.475 μm or more.

In an embodiment, the thickness of the partition portion and the thickness of the element portion may be formed to be about 1.438 μm or less.

According to the display device and the method for manufacturing the same according to an embodiment, by forming the bank layer including the bank portion having liquid repellency, and the partition portion and the element portion having the lyophilic property as one mask, it is possible to reduce a mask process, reduce manufacturing cost, and improve productivity.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic plan view illustrating a layout of lines included in the display device according to an embodiment;

FIG. 3 is a schematic diagram of an equivalent circuit of one sub-pixel according to an embodiment;

FIG. 4 is a schematic plan view illustrating one pixel of the display device according to an embodiment;

FIG. 5 is a schematic cross-sectional view taken along line E1-E1′ of FIG. 4;

FIG. 6 is a schematic cross-sectional view taken along line E2-E2′ of FIG. 4;

FIG. 7 is a schematic plan view illustrating a bank layer according to an embodiment;

FIG. 8 is a schematic cross-sectional view illustrating a bank layer in a light emitting area according to an embodiment;

FIG. 9 is a schematic view illustrating materials of the bank layer according to an embodiment;

FIGS. 10 to 14 are schematic views illustrating a method for manufacturing a bank layer according to an embodiment;

FIG. 15 is a graph illustrating a contact angle with water and a remaining thickness according to an exposure amount of a bank layer according to an embodiment;

FIG. 16 is a schematic view of a light emitting element according to an embodiment;

FIGS. 17 to 20 are schematic views illustrating a method for manufacturing a display device according to an embodiment for each process;

FIG. 21 is a schematic plan view illustrating one sub-pixel of a display device according to another embodiment; and

FIG. 22 is a schematic cross-sectional view taken along line E3-E3′ of FIG. 21.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will convey the scope of the disclosure to those skilled in the art.

The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

When an element is referred to as being “on,” “connected to,” or “coupled to” another element, it may be directly on, connected to, or coupled to the other element or intervening elements or layers may be present. When, however, an element is referred to as being “directly on,” “directly connected to,” or “directly coupled to” another element, there are no intervening elements or layers present. To this end, the term “connected” may refer to physical, electrical, and/or fluid connection, with or without intervening elements

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described with reference to the accompanying drawings.

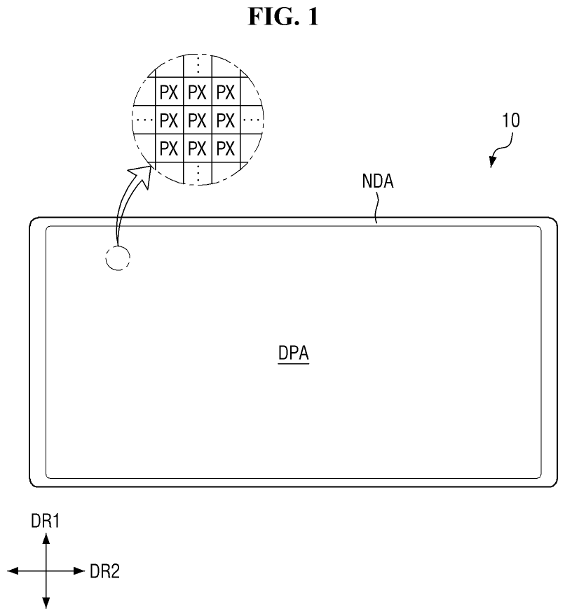

FIG. 1 is a schematic plan view of a display device according to an embodiment.

Referring to FIG. 1, a display device 10 may display a moving image or a still image. The display device 10 may refer to any electronic device that provides a display screen. For example, the display device 10 may include televisions, laptop computers, monitors, billboards, Internet of things devices, mobile phones, smartphones, tablet personal computers (PCs), electronic watches, smartwatches, watch phones, head-mounted displays, mobile communication terminals, electronic notebooks, e-book readers, portable multimedia players (PMPs), navigation systems, game consoles, digital cameras, camcorders, or the like that provide the display screen.

The display device 10 may include a display panel for providing a display screen. Examples of the display panel may include an inorganic light emitting diode display panel, an organic light emitting display panel, a quantum dot light emitting display panel, a plasma display panel, and a field emission display panel. Hereinafter, it is illustrated that an inorganic light emitting diode display panel is used as an example of the display panel, but the disclosure is not limited thereto, and may be applied to other display panels as long as the same technical concept is applicable.

A shape of the display device 10 may be variously changed. For example, the display device 10 may have a shape such as a rectangle with a long width, a rectangle with a long length, a square, a quadrangle with rounded corners (vertices), other polygons, or a circle. A shape of a display area DPA of the display device 10 may also be similar to an overall shape of the display device 10. In FIG. 1, the display device 10 having a rectangular shape with a long length in a second direction DR2 is illustrated as an example.

The display device 10 may include a display area DPA and a non-display area NDA. The display area DPA may be an area in which an image may be displayed, and the non-display area NDA may be an area in which an image is not displayed. The display area DPA may be referred to as an active area, and the non-display area NDA may be referred to as a non-active area. The display area DPA may generally occupy the center of the display device 10.

The display area DPA may include pixels PX. The pixels PX may be arranged in a matrix direction. A shape of each pixel PX may be a rectangular shape or a square shape in a plan view, but is not limited thereto, and may also be a rhombic shape of which each side is inclined with respect to a direction. Each pixel PX may be arranged in a stripe type or an island type. Each of the pixels PX may include one or more light emitting elements that emit light of a specific wavelength band to display a specific color.

The non-display area NDA may be disposed around the display area DPA. The non-display area NDA may entirely or partially surround the display area DPA. The display area DPA may have a rectangular shape, and the non-display area NDA may be disposed adjacent to four sides of the display area DPA. The non-display area NDA may constitute a bezel of the display device 10. Lines or circuit drivers included in the display device 10 may be disposed in each of the non-display areas NDA, or external devices may be mounted thereon.

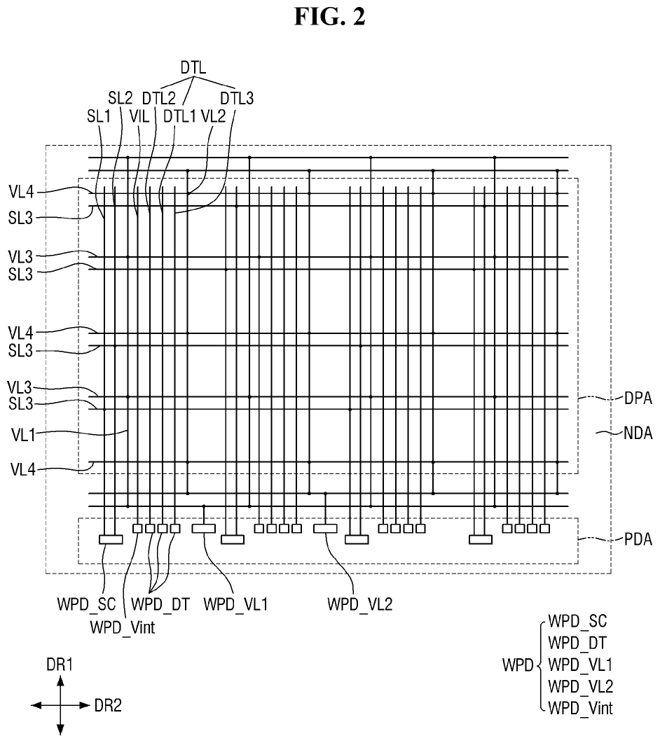

FIG. 2 is a schematic plan view illustrating a layout of lines included in the display device according to an embodiment.

Referring to FIG. 2, the display device 10 may include lines. The display device 10 may include scan lines SL (SL1, SL2, and SL3), data lines DTL (DTL1, DTL2, and DTL3), an initialization voltage line VIL, and voltage lines VL (VL1, VL2, VL3, VL4). Although not illustrated in FIG. 2, other lines may be further disposed in the display device 10.

The first scan line SL1 and the second scan line SL2 may be disposed to extend in a first direction DR1. The first scan line SL1 and the second scan line SL2 may be disposed adjacent to each other, and may be disposed to be spaced apart from other first and second scan lines SL1 and SL2 in a second direction DR2. The first scan line SL1 and the second scan line SL2 may be connected to a scan wiring pad WPD_SC connected to a scan driver (not illustrated). The first scan line SL1 and the second scan line SL2 may be disposed to extend from a pad area PDA disposed in the non-display area NDA to the display area DPA.

The third scan line SL3 may be disposed to extend in the second direction DR2 and may be disposed to be spaced apart from the other third scan lines SL3 in the first direction DR1. A third scan line SL3 may be connected to one or more first scan lines SL1 or one or more second scan lines SL2. In an embodiment, the first scan line SL1 and the second scan line SL2 may be formed of (and/or formed as) a conductive layer disposed on a different layer from the third scan line SL3. The scan lines SL may have a mesh structure in the entirety of the display area DPA, but the disclosure is not limited thereto.

The data lines DTL may be disposed to extend in the first direction DR1. The data line DTL may include a first data line DTL1, a second data line DTL2, and a third data line DTL3, and first to third data lines DTL1, DTL2, and DTL3 may form a pair and may be disposed adjacent to each other. Each of the data lines DTL1, DTL2, and DTL3 may be disposed to extend from the pad area PDA disposed in the non-display area NDA to the display area DPA. However, the disclosure is not limited thereto, and the data lines DTL may also be disposed to be spaced apart from each other at substantially equal intervals between a first voltage line VL1 and a second voltage line VL2 to be described below.

The initialization voltage line VIL may be disposed to extend in the first direction DR1. The initialization voltage line VIL may be disposed between the data lines DTL and the first and second scan lines SL1 and SL2. The initialization voltage line VIL may be disposed to extend from the pad area PDA disposed in the non-display area NDA to the display area DPA.

The first voltage line VL1 and the second voltage line VL2 may be disposed to extend in the first direction DR1, and the third voltage line VL3 and the fourth voltage line VL4 may be disposed to extend in the second direction DR2. The first voltage line VL1 and the second voltage line VL2 may be alternately disposed in the second direction DR2, and the third voltage line VL3 and the fourth voltage line VL4 may be alternately disposed in the first direction DR1. The first voltage line VL1 and the second voltage line VL2 may be disposed to extend in the first direction DR1 and cross (or intersect) the display area DPA, and some of the third voltage line VL3 and the fourth voltage line VL4 may be disposed in the display area DPA, and other lines may be disposed in the non-display area NDA positioned on sides (e.g., both sides) of the display area DPA in the first direction DR1. The first voltage line VL1 and the second voltage line VL2 may be formed of a conductive layer disposed on a layer different from that of the third voltage line VL3 and the fourth voltage line VL4. The first voltage line VL1 may be connected to at least one third voltage line VL3, and the second voltage line VL2 may be connected to at least one fourth voltage line VL4, such that the voltage lines VL may have a mesh structure in the entirety of the display area DPA. However, the disclosure is not limited thereto.

The first scan line SL1, the second scan line SL2, the data line DTL, the initialization voltage line VIL, the first voltage line VL1, and the second voltage line VL2 may be electrically connected to at least one wiring pad WPD. Each wiring pad WPD may be disposed in the non-display area NDA. In an embodiment, each of the wiring pads WPD may be disposed in the pad area PDA positioned on a lower side of the display area DPA, which is the other side of the display area DPA in the first direction DR1. The first scan line SL1 and the second scan line SL2 may be connected to the scan wiring pad WPD_SC disposed in the pad area PDA, and the data lines DTL may be connected to different data wiring pads WPD_DT, respectively. The initialization voltage line VIL may be connected to an initialization wiring pad WPD_Vint, the first voltage line VL1 may be connected to a first voltage wiring pad WPD_VL1, and the second voltage line VL2 may be connected to a second voltage wiring pad WPD_VL2. An external device may be mounted on the wiring pad WPD. The external device may be mounted on the wiring pad WPD through an anisotropic conductive film, ultrasonic bonding, or the like. It is illustrated in FIG. 2 that each of the wiring pads WPD is disposed in the pad area PDA disposed on the lower side of the display area DPA, but the disclosure is not limited thereto. Some of the wiring pads WPD may also be disposed on either an upper side or left and right sides of the display area DPA.

Each pixel PX or sub-pixel SPXn (where n is an integer in a range of 1 to 3) of the display device 10 may include a pixel driving circuit. The above-described lines may apply a driving signal to each pixel driving circuit while passing through each pixel PX or passing around each pixel PX. The pixel driving circuit may include a transistor and a capacitor. The numbers of transistors and capacitors in each pixel driving circuit may be variously changed. According to an embodiment, each sub-pixel SPXn of the display device 10 may have a 3TIC structure in which the pixel driving circuit includes three transistors and a capacitor. Hereinafter, the pixel driving circuit will be described using the 3TIC structure as an example, but the disclosure is not limited thereto, and various other modified structures such as a 2TIC structure, a 7T1C structure, and a 6TIC structure may also be applied.

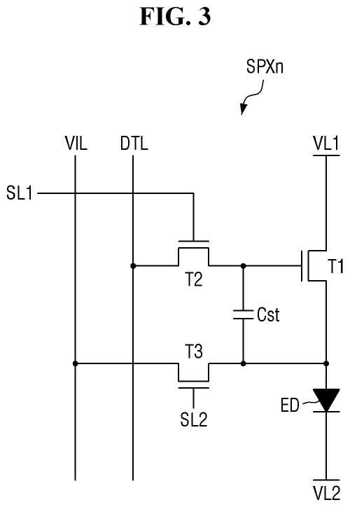

FIG. 3 is a schematic diagram of an equivalent circuit of a sub-pixel according to an embodiment.

Referring to FIG. 3, each sub-pixel PXn of the display device 10 according to an embodiment may include three transistors T1, T2, and T3 and one storage capacitor Cst, in addition to a light emitting element ED.

The light emitting element ED may emit light according to a current supplied through a first transistor T1. The light emitting element ED may include a first electrode, a second electrode, and at least one light emitting diode disposed between the first electrode and the second electrode. The light emitting element may emit light in a specific wavelength band by electrical signals transmitted from the first electrode and the second electrode.

An end of the light emitting element ED may be connected to a source electrode of the first transistor T1, and another end of the light emitting element ED may be connected to a second voltage line VL2 to which a low-potential voltage (hereinafter, referred to as a second power voltage) lower than a high-potential voltage (hereinafter, referred to as a first power voltage) of a first voltage line VL1 is supplied.

The first transistor T1 may adjust a current flowing from the first voltage line VL1, to which the first power voltage is supplied, to the light emitting element ED according to a voltage difference between a gate electrode and the source electrode thereof. As an example, the first transistor T1 may be a driving transistor for driving the light emitting element ED. The gate electrode of the first transistor T1 may be connected to a source electrode of a second transistor T2, the source electrode of the first transistor T1 may be connected to a first electrode of the light emitting element ED, and a drain electrode of the first transistor T1 may be connected to the first voltage line VL1 to which the first power voltage is applied.

The second transistor T2 may be turned on by a scan signal of a first scan line SL1 to connect a data line DTL to the gate electrode of the first transistor T1. A gate electrode of the second transistor T2 may be connected to the first scan line SL1, the source electrode of the second transistor T2 may be connected to the gate electrode of the first transistor T1, and a drain electrode of the second transistor T2 may be connected to the data line DTL.

A third transistor T3 may be turned on by a scan signal of a second scan line SL2 to connect an initialization voltage line VIL to an end of the light emitting element ED. A gate electrode of the third transistor T3 may be connected to the second scan line SL2, a drain electrode of the third transistor T3 may be connected to the initialization voltage line VIL, and a source electrode of the third transistor T3 may be connected to an end of the light emitting element ED and/or the source electrode of the first transistor T1.

In an embodiment, the source electrode and the drain electrode of each of the transistors T1, T2, and T3 are not limited to those described above, and vice versa. Each of the transistors T1, T2, and T3 may be formed as a thin-film transistor. It is illustrated in FIG. 3 that each of the transistors T1, T2, and T3 is formed as an N-type metal oxide semiconductor field effect transistor (MOSFET), but the disclosure is not limited thereto. For example, each of the transistors T1, T2, and T3 may be formed as a P-type MOSFET, or some of the transistors T1, T2, and T3 may be formed as an N-type MOSFET, and others of the transistors T1, T2, and T3 may be formed as a P-type MOSFET.

The storage capacitor Cst may be formed between the gate electrode and the source electrode of the first transistor T1. The storage capacitor Cst may store a difference voltage between a gate voltage and a source voltage of the first transistor T1.

Hereinafter, a structure of a pixel PX of the display device 10 according to an embodiment will be described in detail with reference to other drawings.

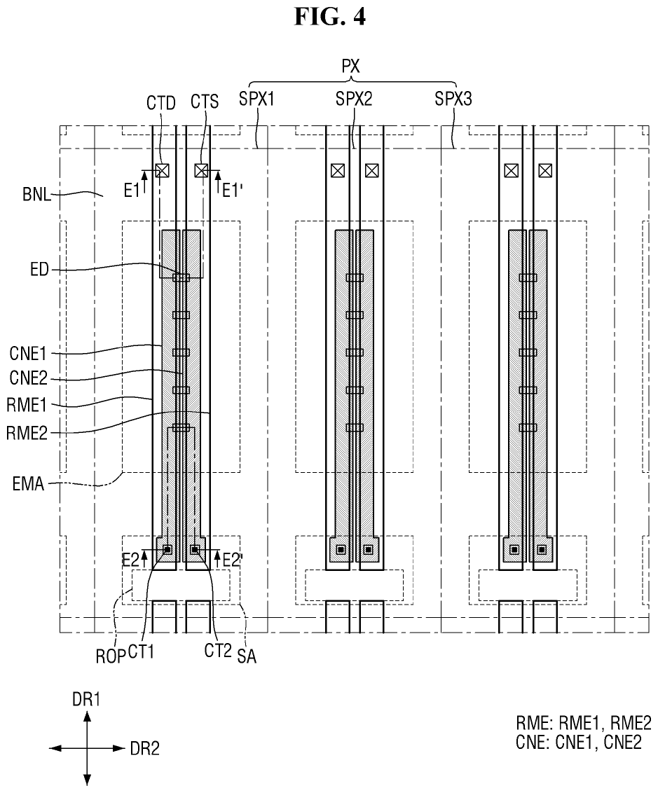

FIG. 4 is a schematic plan view illustrating a pixel of the display device according to an embodiment. FIG. 4 illustrates a planar arrangement of electrodes RME (RME1 and RME2), a bank layer BNL, light emitting elements ED, and connection electrodes CNE (CNE1 and CNE2) disposed in a pixel PX of the display device 10.

Referring to FIG. 4, each of the pixels PX of the display device 10 may include sub-pixels SPXn. For example, a pixel PX may include a first sub-pixel SPX1, a second sub-pixel SPX2, and a third sub-pixel SPX3. The first sub-pixel SPX1 may emit light of a first color, the second sub-pixel SPX2 may emit light of a second color, and the third sub-pixel SPX3 may emit light of a third color. As an example, the first color may be blue, the second color may be green, and the third color may be red. However, the disclosure is not limited thereto, and each of the sub-pixels SPXn may emit light of the same color. In an embodiment, each of the sub-pixels SPXn may emit light of blue color. It is illustrated in FIG. 4 that one pixel PX may include three sub-pixels SPXn, but the disclosure is not limited thereto, and the pixel PX may include a larger number of sub-pixels SPXn.

Each of the sub-pixels SPXn of the display device 10 may include a light emitting area EMA and a non-light emitting area. The light emitting area EMA may be an area in which the light emitting element ED is disposed to emit light of a specific wavelength band. The non-light emitting area may be an area in which the light emitting element ED is not disposed. The light emitted from the light emitting element ED does not reach the non-light emitting area and is not emitted from the non-light emitting area.

The light emitting area EMA may include an area in which the light emitting element ED is disposed and an area adjacent to the light emitting element ED, from which light emitted from the light emitting element ED is emitted. For example, the light emitting area EMA may include an area in which the light emitted from the light emitting elements ED is reflected or refracted by other members and from which the light reflected or refracted by the other members are emitted. The light emitting elements ED may be disposed in each sub-pixel SPXn, and the light emitting area including an area in which the light emitting elements ED are disposed and an area adjacent to the light emitting elements ED may be formed.

It is illustrated in FIG. 4 that the light emitting areas EMA of each sub-pixel SPXn may have a uniform area, but the disclosure is not limited thereto. In some embodiments, each of the light emitting areas EMA of each sub-pixel SPXn may have a different area according to a color or wavelength band of light emitted from the light emitting element ED disposed in the corresponding sub-pixel.

Each sub-pixel SPXn may further include a sub-area SA disposed in the non-light emitting area. The sub-area SA of the corresponding sub-pixel SPXn may be disposed on a lower side of the light emitting area EMA, which is the other side of the light emitting area EMA in the first direction DR1. The light emitting area EMA and the sub-area SA may be alternately arranged in the first direction DR1, and the sub-area SA may be disposed between the light emitting areas EMA of different sub-pixels SPXn spaced apart from each other in the first direction DR1. For example, the light emitting area EMA and the sub-area SA may be alternately arranged in the first direction DR1, and each of the light emitting area EMA and the sub-area SA may be repeatedly arranged in the second direction DR2. However, the disclosure is not limited thereto, and the light emitting areas EMA and the sub-areas SA in the pixels PX may also have an arrangement different from that of FIG. 4.

Since the light emitting element ED is not disposed in the sub-area SA, the light may not be emitted from the sub-area SA, but a portion of the electrode RME disposed in each sub-pixel SPXn may be disposed in the sub-area SA. The electrodes RME disposed in different sub-pixels SPXn may be disposed to be separated from each other based on a separation portion ROP of the sub-area SA.

Each of lines and circuit elements of a circuit layer disposed in each pixel PX and connected to the light emitting element ED may be connected to the first to third sub-pixels SPX1, SPX2, and SPX3. However, the lines and circuit elements may not be disposed to correspond to the area occupied by each sub-pixel SPXn or the light emitting area EMA, but may be disposed regardless of a position of the light emitting area EMA within a pixel PX.

The bank layer BNL may be disposed over a surface of the display area DPA and may expose or surround portions of the sub-pixels SPXn. For example, the bank layer BNL may be disposed to surround the sub-areas SA of the sub-pixels SPXn. The bank layer BNL may be disposed at a boundary between the sub-pixels SPXn adjacent to each other in the first direction DR1 and the second direction DR2, and may also be disposed at a boundary between the sub-areas SA. The light emitting area EMA and the sub-area SA of the display device 10 may be areas divided by an arrangement of the bank layer BNL.

The bank layer BNL may be disposed in a shape including openings on the surface of the display area DPA, including portions extending in the first and second directions DR1 and DR2 in a plan view. The openings of the bank layer BNL may correspond to the sub-area SA.

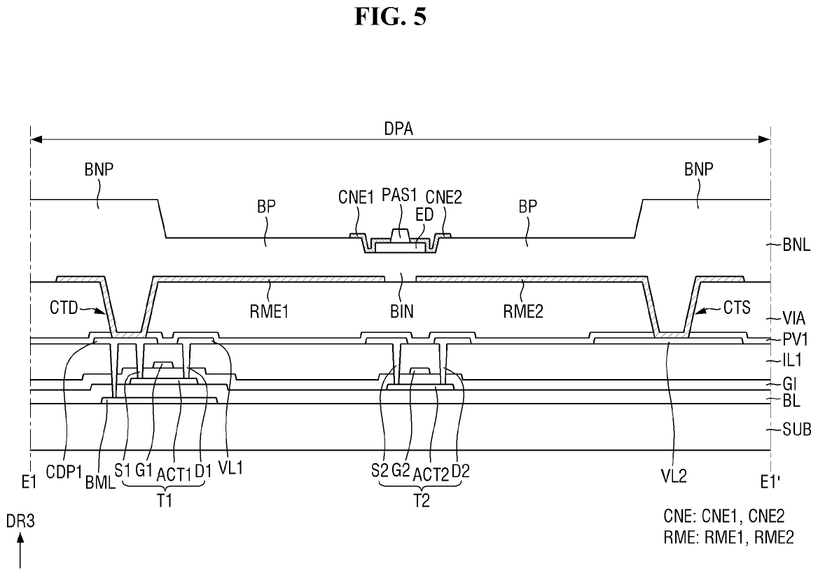

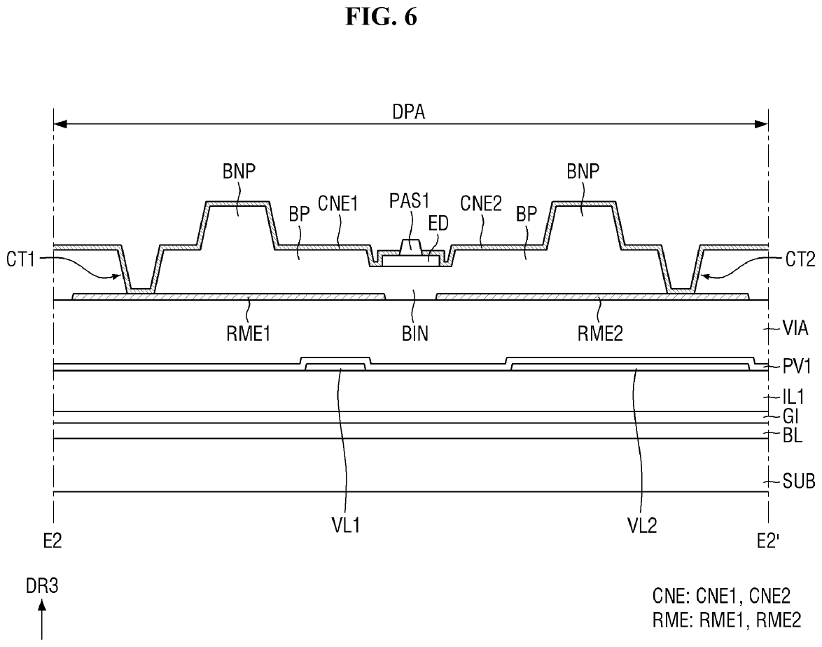

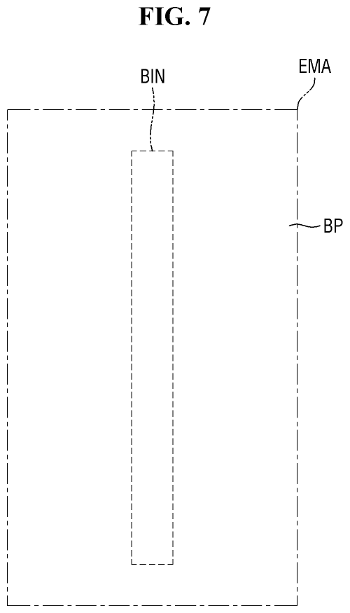

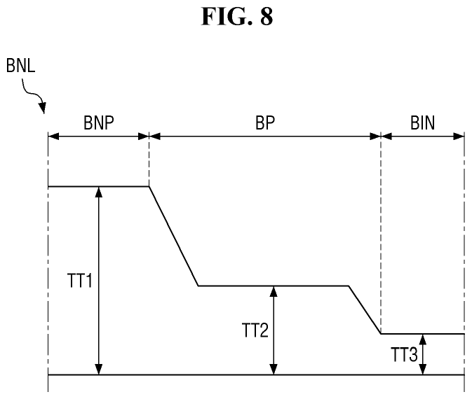

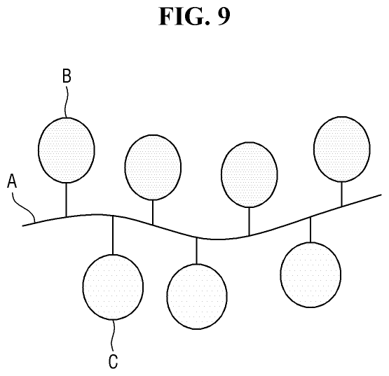

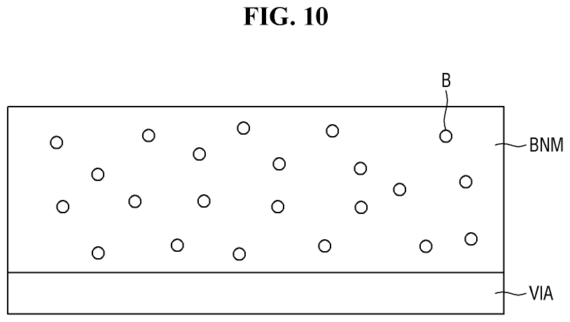

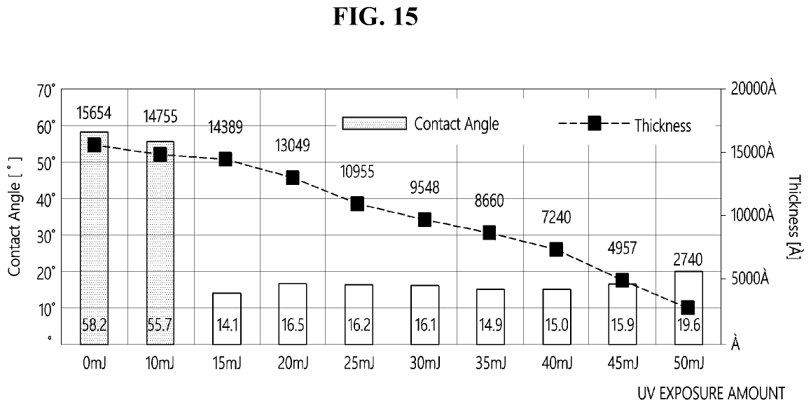

FIG. 5 is a schematic cross-sectional view taken along line E1-E1′ of FIG. 4. FIG. 6 is a schematic cross-sectional view taken along line E2-E2′ of FIG. 4. FIG. 7 is a schematic plan view illustrating a bank layer according to an embodiment. FIG. 8 is a schematic cross-sectional view illustrating a bank layer in a light emitting area according to an embodiment. FIG. 9 is a schematic view illustrating materials of the bank layer according to an embodiment. FIGS. 10 to 14 are schematic views illustrating a method for manufacturing a bank layer according to an embodiment. FIG. 15 is a schematic graph illustrating a contact angle with water and a remaining thickness according to an exposure amount of a bank layer according to an embodiment.

FIG. 5 illustrates a cross section crossing ends (e.g., both ends or opposing ends) of the light emitting element ED and electrode contact holes CTD and CTS disposed in the first sub-pixel SPX1, and FIG. 6 illustrates a cross section crossing ends of the light emitting element ED and contact portions CT1 and CT2 disposed in the first sub-pixel SPX1.

Referring to FIGS. 5 to 8 together with FIG. 4, the display device 10 may include a substrate SUB, and a semiconductor layer, conductive layers, and insulating layers disposed on the substrate SUB. The display device 10 may include electrodes RME (RME1 and RME2), a light emitting element ED, and connection electrodes CNE (CNE1 and CNE2). Each of the semiconductor layer, the conductive layers, and the insulating layers may constitute a circuit layer of the display device 10.

The substrate SUB may be an insulating substrate. The substrate SUB may be made of an insulating material such as glass, quartz, or a polymer resin. The substrate SUB may be a rigid substrate, but may also be a flexible substrate that may be bent, folded, or rolled. The substrate SUB may include a display area DPA and a non-display area NDA surrounding the display area DPA, and the display area DPA may include a light emitting area EMA and a sub-area SA which is a portion of a non-light emitting area.

A first conductive layer may be disposed on the substrate SUB. The first conductive layer may include a bottom metal layer BML, and the bottom metal layer BML may be disposed to overlap a first active layer ACT1 of a first transistor T1. The bottom metal layer BML may perform a function of preventing light from being incident on the first active layer ACT1 of the first transistor T1 and/or stabilizing electrical characteristics of the first transistor T1 by being electrically connected to the first active layer ACT1. However, the bottom metal layer BML may be omitted.

A buffer layer BL may be disposed on the bottom metal layer BML and the substrate SUB. The buffer layer BL may be formed on the substrate SUB to protect transistors of the pixel PX from moisture permeating through the substrate SUB vulnerable to moisture permeation, and may perform a surface planarization function.

A semiconductor layer may be disposed on the buffer layer BL. The semiconductor layer may include the first active layer ACT1 of the first transistor T1 and a second active layer ACT2 of the second transistor T2. The first active layer ACT1 and the second active layer ACT2 may be disposed to partially overlap a first gate electrode G1 and a second gate electrode G2 of a second conductive layer, which will be described below.

The semiconductor layer may include, e.g., polycrystalline silicon, single crystal silicon, an oxide semiconductor, or the like. In another embodiment, the semiconductor layer may include polycrystalline silicon. The oxide semiconductor may be, e.g., an oxide semiconductor containing indium (In). For example, the oxide semiconductor may be at least one of indium tin oxide (ITO), indium zinc oxide (IZO), indium gallium oxide (IGO), indium zinc tin oxide (IZTO), indium gallium tin oxide (IGTO), indium gallium zinc oxide (IGZO), and indium gallium zinc tin oxide (IGZTO).

It is illustrated in the drawing that two transistors T1 and T2 are disposed in the sub-pixel SPXn of the display device 10, but the disclosure is not limited thereto, and the display device 10 may include a larger number of transistors.

A gate insulating layer GI may be disposed on the semiconductor layer and the buffer layer BL in the display area DPA. The gate insulating layer GI may not be disposed in the pad area PDA. The gate insulating layer GI may serve as a gate insulating film for each of the transistors T1 and T2. It is illustrated in the drawing that the gate insulating layer GI is entirely disposed on the buffer layer BL, but the disclosure is not limited thereto. In some embodiments, the gate insulating layer GI may be patterned together with first and second gate electrodes G1 and G2 of a second conductive layer to be described below, and may be partially disposed between the second conductive layer and the first and second active layers ACT1 and ACT2 of the semiconductor layer.

A second conductive layer may be disposed on the gate insulating layer GI. The second conductive layer may include the first gate electrode G1 of the first transistor T1 and the second gate electrode G2 of the second transistor T2. The first gate electrode G1 may be disposed to overlap a channel region of the first active layer ACT1 in the third direction DR3, which is a thickness direction, and the second gate electrode G2 may be disposed to overlap a channel region of the second active layer ACT2 in the third direction DR3, which is a thickness direction. Although not illustrated in the drawings, the second conductive layer may further include an electrode of a storage capacitor.

An interlayer insulating layer IL1 may be disposed on the second conductive layer. The interlayer insulating layer IL1 may perform a function of an insulating film between the second conductive layer and other layers disposed on the second conductive layer, and may protect the second conductive layer.

A third conductive layer may be disposed on the interlayer insulating layer IL1. The third conductive layer may include a first voltage line VL1 and a second voltage line VL2, a first conductive pattern CDP1, and first and second source electrodes S1 and S2 and first and second drain electrodes D1 and D2 of each of the transistors T1 and T2 disposed in the display area DPA. Although not illustrated in the drawings, the third conductive layer may further include another electrode of the storage capacitor.

A high-potential voltage (or a first power voltage) transmitted to a first electrode RME1 may be applied to the first voltage line VL1, and a low-potential voltage (or a second power voltage) transmitted to a second electrode RME2 may be applied to the second voltage line VL2. A portion of the first voltage line VL1 may contact the first active layer ACT1 of the first transistor T1 through a contact hole penetrating through the interlayer insulating layer IL1 and the gate insulating layer GI. The first voltage line VL1 may serve as a first drain electrode D1 of the first transistor T1. The second voltage line VL2 may be directly connected to a second electrode RME2 to be described below.

The first conductive pattern CDP1 may contact the first active layer ACT1 of the first transistor T1 through a contact hole penetrating through the interlayer insulating layer IL1 and the gate insulating layer GI. The first conductive pattern CDP1 may contact the bottom metal layer BML through another contact hole. The first conductive pattern CDP1 may serve as a first source electrode SI of the first transistor T1. The first conductive pattern CDP1 may be connected to a first electrode RME1 or a first connection electrode CNE1 to be described below. The first transistor T1 may transmit the first power voltage applied from the first voltage line VL1 to the first electrode RME1 or the first connection electrode CNE1.

A second source electrode S2 and a second drain electrode D2 may contact the second active layer ACT2 of the second transistor T2 through contact holes penetrating through the interlayer insulating layer IL1 and the first gate insulating layer GI. The second transistor T2 may be any one of the switching transistors described above with reference to FIG. 3. The second transistor T2 may transmit the signal applied from the data line DTL of FIG. 3 to the first transistor T1, or may transmit the signal applied from the initialization voltage line VIL of FIG. 3 to another electrode of the storage capacitor.

A passivation layer PVI may be disposed on the third conductive layer. The passivation layer PVI may serve as an insulating film between the third conductive layer and other layers and protect the third conductive layer.

The buffer layer BL, the gate insulating layer GI, the interlayer insulating layer IL1, and the passivation layer PVI described above may be formed as inorganic layers alternately stacked each other. For example, the buffer layer BL, the gate insulating layer GI, the interlayer insulating layer IL1, and the passivation layer PVI may be formed as a double layer in which an inorganic layer including, e.g., at least one of silicon oxide (SiOₓ), silicon nitride (SiNₓ), and silicon oxynitride (SiOₓN_{y}) is stacked, or multiple layers in which these layers are alternately stacked each other. However, the disclosure is not limited thereto. In an embodiment, the buffer layer BL, the gate insulating layer GI, the interlayer insulating layer IL1, and the passivation layer PVI may be formed as an inorganic layer including the above-described insulating material. In some embodiments, the interlayer insulating layer IL1 may be formed of an organic insulating material such as polyimide (PI).

A via layer VIA may be disposed on the third conductive layer in the display area DPA. The via layer VIA may include an organic insulating material, for example, an organic insulating material such as polyimide (PI) to compensate for a step caused by lower conductive layers and have a flat upper surface. However, in some embodiments, the via layer VIA may be omitted.

The display device 10 may include, as a display element layer disposed on the via layer VIA, electrodes RME (RME1 and RME2), a bank layer BNL, light emitting elements ED, and connection electrodes CNE (CNE1 and CNE2). The display device 10 may include a first insulating layer PAS1 disposed on the via layer VIA.

The electrodes RME (RME1 and RME2) may be disposed for each sub-pixel SPXn in a shape extending in a direction. The electrodes RME1 and RME2 may extend in the first direction DR1 to be disposed in the light emitting area EMA and the sub-area SA of the sub-pixel SPXn, and may be disposed to be spaced apart from each other in the second direction DR2. The electrodes RME may be electrically connected to a light emitting element ED to be described below, but the disclosure is not limited thereto, and the electrodes RME may not be electrically connected to the light emitting element ED.

The display device 10 may include a first electrode RME and a second electrode RME2 disposed in each sub-pixel SPXn. The first electrode RME1 may be disposed on the left side of the center of the light emitting area EMA, and the second electrode RME2 may be spaced apart from the first electrode RME1 in the second direction DR2 and may be disposed on the right side of the center of the light emitting area EMA. The first electrode RME1 may be disposed on a via layer VIA, and the second electrode RME2 may be disposed on the via layer VIA. The first electrode RME1 and the second electrode RME2 may be partially disposed in the corresponding sub-pixel SPXn and the sub-area SA beyond the bank layer BNL. The first electrode RME1 and the second electrode RME2 of different sub-pixels SPXn may be spaced apart from each other based on the separation portion ROP positioned in the sub-area SA of any one sub-pixel SPXn.

It is illustrated in the drawings that the two electrodes RME have a shape extending in the first direction DR1 for each sub-pixel SPXn, but the disclosure is not limited thereto. The electrodes RME may be disposed, or the electrodes RME may be partially bent and may have different widths depending on positions thereof. The first electrode RME1 and the second electrode RME2 may be entirely disposed to be flat on the via layer VIA. An interval by which the first electrode RME1 and the second electrode RME2 are spaced apart from each other in the second direction DR2 may be smaller than a length of the light emitting element ED. At least partial areas of the first electrode RME1 and the second electrode RME2 may be directly disposed on the via layer VIA such that the first electrode RME1 and the second electrode RME2 may be disposed on the same plane.

Each of the electrodes RME may directly contact the third conductive layer through the electrode contact holes CTD and CTS at portions overlapping the bank layer BNL between the light emitting area EMA and the sub-area SA. A first electrode contact hole CTD may be formed in an area where the bank layer BNL and the first electrode RME1 overlap each other, and a second electrode contact hole CTS may be formed in an area where the bank layer BNL and the second electrode RME2 overlap each other. The first electrode RME1 may contact the first conductive pattern CDP1 through the first electrode contact hole CTD penetrating through the via layer VIA and the passivation layer PV1. The second electrode RME2 may contact the second voltage line VL2 through the second electrode contact hole CTS penetrating through the via layer VIA and the passivation layer PV1. The first electrode RME1 may be electrically connected to the first transistor T1 through the first conductive pattern CDP1 and may be applied with the first power voltage, and the second electrode RME2 may be electrically connected to the second voltage line VL2 and be applied with the second power voltage. However, the disclosure is not limited thereto. In another embodiment, each of the electrodes RME1 and RME2 may not be electrically connected to the voltage lines VL1 and VL2 of the third conductive layer, and a connection electrode CNE to be described below may be directly connected to the third conductive layer.

The electrodes RME may include, e.g., a conductive material having high reflectivity. For example, the electrodes RME may include a metal such as silver (Ag), copper (Cu), aluminum (Al), or the like, or may have a structure in which an alloy including aluminum (Al), nickel (Ni), lanthanum (La), or the like and a metal layer such as titanium (Ti), molybdenum (Mo), and niobium (Nb) are stacked each other. In some embodiments, the electrodes RME may be formed as a double layer or multiple layers in which an alloy including aluminum (Al) and one or more metal layers made of titanium (Ti), molybdenum (Mo), and niobium (Nb) are stacked each other.

However, the disclosure is not limited thereto, and each of the electrodes RME may further include a transparent conductive material. For example, each electrode RME may include a material such as ITO, IZO, or ITZO. In some embodiments, each of the electrodes RME may have a structure in which a transparent conductive material and a metal layer having high reflectivity are stacked each other in one or more layers, or may be formed as a single layer including the transparent conductive material and the metal layer having the high reflectivity. For example, each electrode RME may have a stacked structure such as ITO/Ag/ITO, ITO/Ag/IZO, or ITO/Ag/ITZO/IZO. The electrodes RME may be electrically connected to the light emitting element ED and may reflect some of the light emitted from the light emitting element ED in an upper direction of the substrate SUB.

The bank layer BNL may be disposed on the via layer VIA and the electrodes RME1 and RME2. The bank layer BNL may be disposed on the entire surface of the display area DPA, and may be disposed on the via layer VIA and the electrodes RME. The bank layer BNL may protect the electrodes RME and insulate different electrodes RME from each other.

The bank layer BNL may include a bank portion BNP, a partition portion BP, and/or an element portion BIN having different thicknesses. For example, the bank layer BNL may include a bank portion BNP, a partition portion BP having a thickness different from that of the bank portion BNP, and an element portion BIN having a thickness different from that of the bank portion BNP and the partition portion BP. The bank portion BNP, the partition portion BP, and the element portion BIN may be integrated with (or integral with) each other, and may be referred to as a portion of the bank layer BNL according to the arrangement positions and thicknesses.

The element portion BIN of the bank layer BNL may be disposed in the light emitting area EMA of each sub-pixel SPXn. The element portion BIN may have a shape extending in the first direction DR1 and may be surrounded by the partition portion BP. For example, the element portion BIN may be disposed at the center of the partition portion BP, and all sides of the element portion BIN may be surrounded by the partition portion BP. The element portion BIN may be in an area where the light emitting elements ED are seated (or disposed).

The partition portion BP may be disposed in the light emitting area EMA of each sub-pixel SPXn. The partition portion BP may have a shape surrounding the element portion BIN. The partition portion BP may be an area other than the bank portion BNP and the element portion BIN. The light emitting elements ED may be disposed between the partition portions BP. For example, the light emitting elements ED may be disposed on the element portion BIN between the partition portions BP.

The partition portion BP may extend in the first and second directions DR1 and DR2 to be integrated with a portion of the bank portion BNP of the bank layer BNL surrounding the light emitting area EMA. A length of the partition portion BP in the first direction DR1 may be the same as a length of the light emitting area EMA in the first direction DR1 and may be greater than a length of the element portion BIN in the first direction DR1. The partition portion BP may also be disposed in the sub-area SA. The partition portion BP may be disposed to overlap the first contact portion CT1 and the second contact portion CT2 of the sub-area SA. The partition portion BP of the sub-area SA may be disposed to be spaced apart from the partition portion BP of the light emitting area EMA with the bank portion BNP interposed (or disposed) therebetween.

The partition portion BP may have an inclined surface, and the inclined surface of the partition portion BP may have a flat surface or a curved surface having a curvature (e.g., a predetermined or selectable curvature). Unlike illustrated in the drawings, the partition portion BP may have an outer surface in a curved shape having a curvature (e.g., a predetermined or selectable curvature), for example, a semicircular or semielliptical shape in a cross-sectional view.

The bank portion BNP of the bank layer BNL may include portions extending in the first direction DR1 and the second direction DR2, and may surround each of the sub-pixels SPXn. The bank portion BNP may surround the light emitting area EMA and the sub-area SA of each sub-pixel SPXn and may distinguish the light emitting area EMA and the sub-area SA, and may be integrated with the partition portion BP disposed in the light emitting area EMA and the partition portion BP disposed in the sub-area SA. The bank portion BNP of the bank layer BNL may surround the outermost periphery of the display area DPA and may distinguish the display area DPA and the non-display area NDA. The bank layer BNL may be entirely disposed in the display area DPA, and an area opened by the bank layer BNL in the display area DPA may be the separation portion ROP of the sub-area SA.

The bank portion BNP of the bank layer BNL may have a greater thickness than the partition portion BP and the element portion BIN. A thickness TT1 of the bank portion BNP may be greater than a thickness TT2 of the partition portion BP. The bank portion BNP may have a thick thickness to prevent ink from overflowing to adjacent sub-pixels SPXn during an inkjet printing process in a process of manufacturing the display device 10. The thickness TT1 of the bank portion BNP of the bank layer BNL may be about 1.475 μm or more. As will be described below, in case that the thickness TT1 of the bank portion BNP is about 1.475 μm or more, a surface of the bank portion BNP may exhibit liquid repellency, thereby preventing ink from overflowing to the adjacent sub-pixels SPXn. For example, the thickness TT1 of the bank portion BNP may be in a range of about 1.475 μm to about 5 μm.

The partition portion BP of the bank layer BNL may have a greater thickness than the element portion BIN. A thickness TT2 of the partition portion BP may be greater than a thickness TT3 of the element portion BIN. The partition portion BP may act as a partition to prevent the light emitting elements ED, included in the ink, from being separated from the element portion BIN after being seated on the element portion BIN during the process of manufacturing the display device 10. The thickness TT2 of the partition portion BP may be about 1.438 μm or less. As will be described below, when the thickness TT2 of the partition portion BP is about 1.438 μm or less, the surface of the partition portion BP may exhibit a lyophilic property, so that the ink may be evenly spread on the partition portion BP. For example, the thickness TT2 of the partition portion BP may be about 0.5 μm to about 1.438 μm.

The element portion BIN of the bank layer BNL may have a smaller thickness than the partition portion BP and the bank portion BNP. The thickness TT3 of the element portion BIN may be smaller than the thickness TT2 of the partition portion BP and may be smaller than the thickness TT1 of the bank portion BNP. The element portion BIN may serve as a space in which the light emitting elements ED included in the ink are seated and aligned during the process of manufacturing the display device 10. The thickness TT3 of the element portion BIN may be about 0.5 μm or less. As will be described below, when the thickness TT3 of the element portion BIN is about 0.5 μm or less, the surface of the element portion BIN may exhibit a lyophilic property, so that the ink may be evenly spread on the element portion BIN. For example, the thickness TT3 of the element portion BIN may be in a range of about 0.1 μm to about 0.5 μm.

In an embodiment, the bank layer BNL may include fluorine F. Fluorine may be included on and inside the bank layer BNL. An atomic ratio of fluorine on the surface of the bank portion BNP of the bank layer BNL may be greater than an atomic ratio of fluorine on the surfaces of the partition portion BP and the element portion BIN. Fluorine may act to exhibit liquid repellency, and the higher the atomic ratio of fluorine is, the more liquid repellency may be exhibited. For example, the atomic ratio of fluorine on the surface of the bank portion BNP may be about 11% or more, and the atomic ratio of fluorine on the surfaces of the partition portion BP and the element portion BIN may be about 9.1% or less. For example, the atomic ratio of fluorine on the surface of the bank portion BNP may be about 11% to 50%. The atomic ratio of fluorine on the surface of the bank portion BNP may be greater than the atomic ratio of fluorine at the center of the bank portion BNP in the thickness direction. In some embodiments, the atomic ratio of fluorine may gradually decrease from the surface of the bank portion BNP toward the bottom thereof. The atomic ratio of fluorine on the surface of each of the partition portion BP and the element portion BIN may be greater than the atomic ratio of fluorine inside each of the partition portion BP and the element portion BIN. In some embodiments, the atomic ratio of fluorine may gradually decrease from the surface of each of the partition portion BP and the element portion BIN toward the bottom thereof.

The bank layer BNL may include contact portions CT1 and CT2. The contact portions CT1 and CT2 may be formed at portions where the connection electrodes CNE and the electrodes RME are connected in the sub-area SA. The bank layer BNL may partially expose lower layers at the portions where the contact portions CT1 and CT2 are formed.

The contact portions CT1 and CT2 formed in the bank layer BNL may be disposed to overlap different electrodes RME, respectively. For example, the contact portions CT1 and CT2 may include a first contact portion CT1 disposed to overlap the first electrode RME1 and a second contact portion CT2 disposed to overlap the second electrode RME2 in the sub-area SA. The first contact portion CT1 and the second contact portion CT2 may penetrate through the bank layer BNL to expose a portion of an upper surface of the first electrode RME1 or the second electrode RME2 on a lower side thereof. The electrode RME exposed by each of the contact portions CT1 and CT2 may contact the connection electrode CNE.

The light emitting elements ED may be disposed in the light emitting area EMA. The light emitting elements ED may be disposed on the element portion BIN of the bank layer BNL, and may be arranged to be spaced apart from each other in the first direction DR1. In an embodiment, the light emitting elements ED may have a shape extending in a direction, and have ends each disposed on different electrodes RME. For example, the light emitting element ED may have a first end disposed on the first electrode RME1 and a second end disposed on the second electrode RME2. The light emitting element ED may have a length greater than the interval between the electrodes RME spaced apart from each other in the second direction DR2. The light emitting elements ED may be arranged so that an extension direction thereof is substantially perpendicular to the first direction DR1 in which the electrodes RME extend. However, the disclosure is not limited thereto, and the light emitting elements ED may be disposed so that the extension direction thereof faces the second direction DR2 or a direction obliquely inclined with respect to the second direction DR2.

As described below, the light emitting element ED may include semiconductor layers disposed in the extended direction, and the semiconductor layers may be sequentially disposed in a direction parallel to the upper surface of the substrate SUB. However, the disclosure is not limited thereto, and in case that the light emitting element ED has another structure, the semiconductor layers may also be disposed in a direction perpendicular to the substrate SUB.

The light emitting elements ED disposed in each sub-pixel SPXn may emit light of different wavelength bands according to materials of the above-described semiconductor layers. However, the disclosure is not limited thereto, and the light emitting elements ED disposed in each sub-pixel SPXn may include semiconductor layers made of the same material and emit light of the same color.

The light emitting elements ED may contact the connection electrodes CNE (CNE1 and CNE2) to be electrically connected to the electrodes RME and the conductive layers under the via layer VIA, and may be applied with electrical signals to emit light of a specific wavelength band.

The first insulating layer PAS1 may be disposed on the light emitting elements ED and the bank layer BNL. The first insulating layer PAS1 may cover the light emitting elements ED and may be directly disposed on the element portion BIN between the partition portions BP of the bank layer BNL. The first insulating layer PAS1 may extend in the first direction DR1 and be disposed to partially cover an outer surface of the light emitting element ED, and may not cover sides or ends of the light emitting element ED. The first insulating layer PAS1 may protect the light emitting elements ED and fix the light emitting elements ED in the process of manufacturing the display device 10.

Each of the first insulating layers PAS1 may include an inorganic insulating material or an organic insulating material. At least one of the first insulating layers PAS1 may have a structure in which insulating layers are alternately or repeatedly stacked each other. In an embodiment, each of the first insulating layers PAS1 may be any one of silicon oxide (SiOₓ), silicon nitride (SiNₓ), and silicon oxynitride (SiOₓN_{y}). The first insulating layers PAS1 may be made of the same material, or may be partially made of the same material and partially made of different materials, or may be made of different materials.

The connection electrodes CNE (CNE1 and CNE2) may be disposed on the light emitting element ED and the bank layer BNL. The connection electrodes CNE may each have a shape extending in a direction and may be disposed to be spaced apart from each other. Each of the connection electrodes CNE may contact the light emitting element ED and may be electrically connected to the third conductive layer.

The connection electrodes CNE may include a first connection electrode CNE1 and a second connection electrode CNE2 disposed in each sub-pixel SPXn. The first connection electrode CNE1 may have a shape extending in the first direction DR1, and may be disposed on the first electrode RME or the element portion BIN or the partition portion BP of the bank layer BNL. The first connection electrode CNE1 may partially overlap the first electrode RME1 and may be disposed from the light emitting area EMA to the sub-area SA beyond the bank layer BNL. The second connection electrode CNE2 may have a shape extending in the first direction DR1, and may be disposed on the second electrode RME2, the element portion BIN, and/or the partition portion BP of the bank layer BNL. The second connection electrode CNE2 may partially overlap the second electrode RME2 and may be disposed from the light emitting area EMA to the sub-area SA beyond the bank layer BNL. The first connection electrode CNE1 and the second connection electrode CNE2 may contact the light emitting elements ED, and may be electrically connected to the electrodes RME or a conductive layer on a lower side thereof.

For example, the first connection electrode CNE1 and the second connection electrode CNE2 may be disposed on side surfaces of the first insulating layer PAS1, respectively, and may contact the light emitting elements ED. The first connection electrode CNE1 may partially overlap the first electrode RME1 and may contact ends of the light emitting elements ED. The second connection electrode CNE2 may partially overlap the second electrode RME2 and may contact other ends of the light emitting elements ED. The connection electrodes CNE may be disposed across the light emitting area EMA and the sub-area SA. The connection electrodes CNE may contact the light emitting elements ED at portions thereof disposed in the light emitting area EMA, and may be electrically connected to the third conductive layer at portions thereof disposed in the sub-area SA.

In an embodiment, in the display device 10, the connection electrodes CNE may contact the electrodes RME through the contact portions CT1 and CT2 disposed in the sub-area SA. The first connection electrode CNE1 may contact the first electrode RME1 through the first contact portion CT1 penetrating through the bank layer BNL in the sub-area SA. The second connection electrode CNE2 may contact the second electrode RME2 through the second contact portion CT2 penetrating through the bank layer BNL in the sub-area SA. Each of the connection electrodes CNE may be electrically connected to the third conductive layer through each of the electrodes RME. The first connection electrode CNE1 may be electrically connected to the first transistor T1 and be applied with the first power voltage, and the second connection electrode CNE2 may be electrically connected to the second voltage line VL2 and be applied with the second power voltage. Each of the connection electrodes CNE may contact the light emitting element ED in the light emitting area EMA to transmit the power voltage to the light emitting element ED.

However, the disclosure is not limited thereto. In some embodiments, the connection electrodes CNE may directly contact the third conductive layer, and may also be electrically connected to the third conductive layer through other patterns other than the electrodes RME.

The connection electrodes CNE may include a conductive material. For example, the connection electrodes CNE may include ITO, IZO, ITZO, aluminum (Al), or the like. As an example, the connection electrodes CNE may include a transparent conductive material, and the light emitted from the light emitting elements ED may transmit through the connection electrodes CNE and then be emitted.

Although not illustrated in the drawing, other insulating layers may be further disposed on the first connection electrode CNE1, the second connection electrode CNE2, and the second insulating layer PAS2. The insulating layer may serve to protect the members, disposed on the substrate SUB, from external environments.

As described above, the bank layer BNL may have liquid repellency and a lyophilic property. Specifically, the bank portion BNP of the bank layer BNL may have liquid repellency, and the partition portion BP and the element portion BIN may have a lyophilic property.

The bank layer BNL may be made of a bank layer composition for manufacturing the bank layer BNL. The bank layer composition may include a polymer resin. The bank layer composition may include a polymer resin, a fluorine-based liquid repellent additive, and a photoactive compound.

The polymer resin may include polyimide represented by Chemical Formula 1 below, and the fluorine-based liquid repellent additive may be an organic compound containing fluorine.

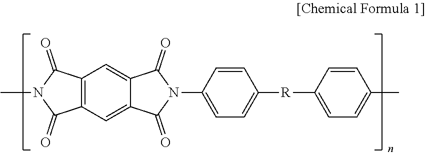

The photoactive compound may be a material that absorbs UV and changes chemical solubility in a developing solution. In an embodiment, the photoactive compound may be manufactured in a positive type in which a coating solution for manufacturing the bank layer BNL reacts with UV and is dissolved in the developing solution.

As illustrated in FIG. 9, the bank layer composition may include a liquid repellent part B and a lyophilic part C coupled to a main chain A. The main chain A may be the above-described polymer resin, for example, polyimide, the liquid repellent part B may be a functional group containing fluorine, and the lyophilic part C may be a functional group containing-OH group.

A manufacturing method and a mechanism for enabling the bank layer BNL to have both liquid repellency and a lyophilic property will be described with reference to FIGS. 10 to 14.

Referring to FIG. 10, a bank material layer BNM may be formed by applying a bank layer composition on the via layer VIA. The bank layer composition may be applied by a solution process such as spin coating, inkjet printing, or the like. The bank material layer BNM may be formed to have a thickness of about 1.458 μm or more. As described above, the liquid repellent part B may be included in the bank material layer BNM.

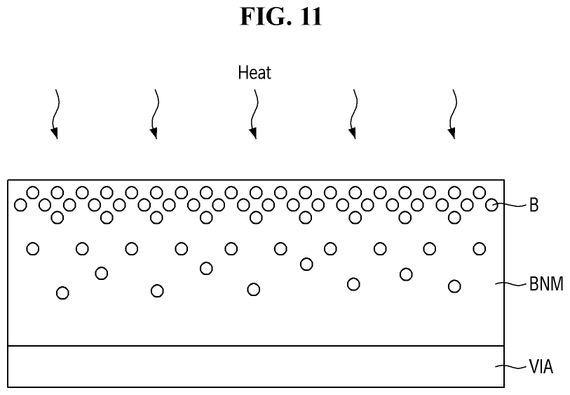

Referring to FIG. 11, a soft bake process may be performed on the bank material layer BNM. In the soft bake process, heat treatment may be performed at a temperature (e.g., a predetermined or selectable temperature). In the soft bake process, in the liquid repellent part B present in the bank material layer BNM, a fluorine component, which is a single molecule, may be gathered toward a surface of the bank material layer BNM. Accordingly, a large number of fluorine components may exist on an upper side of the bank material layer BNM, and the fluorine component may decrease toward a lower side thereof.

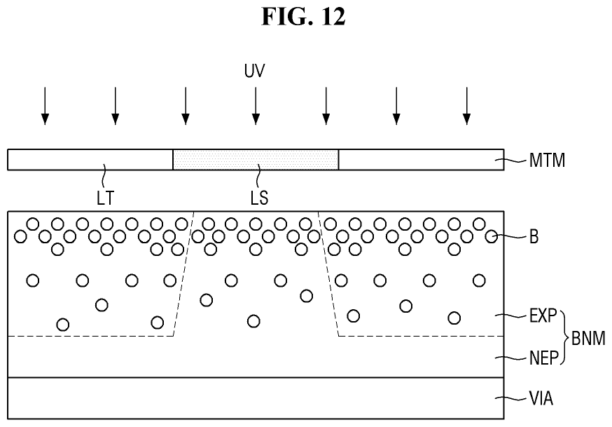

Referring to FIG. 12, a mask MTM including a light blocking portion LS and a transmission portion LT may be aligned on the bank material layer BNM. The light blocking portion LS may be an area that blocks light during exposure, and the transmission portion LT may be an area that transmits light. Ultraviolet (UV) light may be exposed to the bank material layer BNM from above the mask MTM. By the exposure process, an exposed portion EXP exposed to ultraviolet (UV) light and an unexposed portion NEP may be formed in the bank material layer BNM. In the exposure process, the photoactive compound may react and combine with the polymer resin to change the chemical solubility of the developing solution.

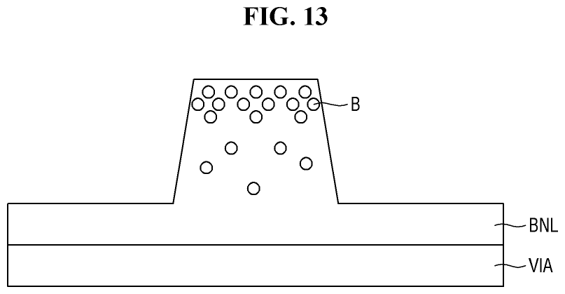

Referring to FIG. 13, a developing process may be performed on the bank material layer BNM. In the developing process, a developing solution may be applied on the bank material layer BNM to remove the exposed portion EXP and leave the unexposed portion NEP. As described above, the bank layer composition may be of a positive type, and the exposed portion EXP exposed to ultraviolet light may be removed by the developing solution.

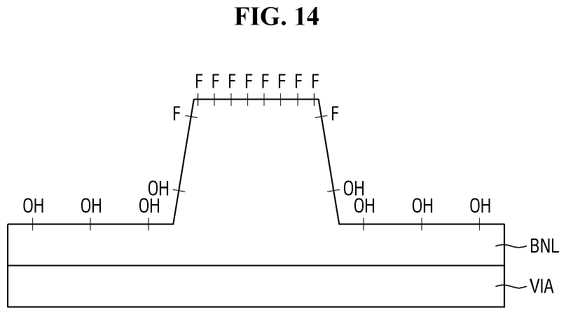

Referring to FIG. 14, the bank layer BNL may be finally manufactured by curing the bank material layer BNM. In an area corresponding to the unexposed portion NEP of the bank material layer BNM, a large number of fluorine components of the liquid repellent part may be present on the surface to exhibit liquid repellency. In an area corresponding to the exposed portion EXP of the bank material layer BNM, the fluorine component may be insignificant, and —OH groups formed by combining the polymer resin and the photoactive compound may be exposed to the surface to exhibit a lyophilic property.

As a result, the bank layer BNL formed to have a great thickness may exhibit liquid repellency, and the bank layer BNL formed to have a small thickness may exhibit a lyophilic property. Accordingly, the bank portion BNP of the bank layer BNL may exhibit liquid repellency, and the partition portion BP and element portion BIN may exhibit a lyophilic property.

FIG. 15 illustrates a contact angle with water due to a decrease in thickness according to an exposure amount of the bank layer BNL.

As illustrated in FIG. 15, a bank layer BNL having a thickness of about 15,654 Å formed without exposure to ultraviolet light exhibited a contact angle of about 60 degrees, and a bank layer BNL having a thickness of about 14,755 Å formed by exposure to a small amount of ultraviolet light of about 10 mJ exhibited a contact angle of about 55 degrees. For example, a surface of the bank layer BNL formed without exposure to ultraviolet light or by exposure to a small amount of ultraviolet light exhibited liquid repellency.

On the other hand, bank layers BNL having a thickness of about 14,389 Å or less formed by exposure to ultraviolet light of about 15 mJ or more exhibited a contact angle of about 20 degrees or less. For example, a surface of the bank layer BNL formed by exposure to ultraviolet light of about 15 mJ or more exhibited a lyophilic property.

Table 1 below illustrates the result of analyzing components in the bank layer BNL through XPS analysis after forming the bank layer BNL. After the bank layer BNL was applied to have a thickness of about 1.5 μm, a portion thereof was exposed, and another portion thereof was unexposed to manufacture the bank layer BNL. In Table 1 below, the surface is the surface of the bank layer BNL, and the inside of the film means the center of the unexposed portion and the center of the exposed portion of the bank layer BNL. As a comparative example, a polyimide bank layer containing no fluorine-based liquid repellent additive was illustrated.

TABLE 1

| | Contact | | | | | |
|---|---|---|---|---|---|---|
| / | Angle | Section | Atomic Ratio (%) | | | |
| / | (°) | — | C1s | F1s | N1s | O1s |
| Comparative Example | — | — | 69.39 | 7.84 | 4.74 | 16.60 |
| Unexposed Portion | 51.6 | Surface | 66.21 | 11.97 | 1.65 | 20.01 |
| | — | Inside of | 72.62 | 10.09 | 3.27 | 14.02 |
| | | Film | | | | |
| Exposed Portion | 5 | Surface | 60.05 | 9.08 | 3.51 | 27.19 |
| | | Inside of | 73.81 | 8.55 | 3.01 | 14.64 |
| | | Film | | | | |

Referring to Table 1, the surface of the bank layer BNL of the unexposed portion showed a contact angle with water of about 51.6° and an atomic ratio of fluorine of about 11.97%. On the other hand, the surface of the bank layer BNL of the exposed portion showed a contact angle with water of about 5° and an atomic ratio of fluorine of about 9.08%.

Through this, it was confirmed that the surface of the unexposed portion of the bank layer BNL exhibited liquid repellency due to a relatively high atomic ratio of fluorine, and the surface of the exposed portion of the bank layer BNL exhibited a lyophilic property due to a relatively low atomic ratio of fluorine.

In an embodiment, the bank portion BNP of the bank layer BNL may be formed without exposure to ultraviolet light to exhibit liquid repellency, and the partition portion BP and the element portion BIN may be formed by exposure to ultraviolet light to exhibit a lyophilic property.

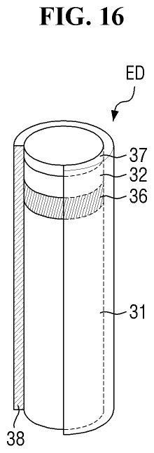

FIG. 16 is a schematic view of a light emitting element according to an embodiment.

Referring to FIG. 16, the light emitting element ED may be a light emitting diode. Specifically, the light emitting element ED may be an inorganic light emitting diode having a size of a nanometer to micrometer unit and made of an inorganic material. The light emitting element ED may be aligned between two electrodes in which polarities are formed when an electric field is formed in a specific direction between the two electrodes facing each other.

The light emitting element ED according to an embodiment may have a shape extending in a direction. The light emitting element ED may have a shape such as a cylinder, a rod, a wire, or a tube. However, the shape of the light emitting element ED is not limited thereto, and the light emitting element ED may have various shapes. For example, the light emitting element ED may have a polygonal prismatic shape such as a cubic shape, a rectangular parallelepiped shape, or a hexagonal prismatic shape or may have a shape extending in a direction and having a partially inclined outer surface.

The light emitting element ED may include a semiconductor layer doped with an arbitrary conductive (e.g., p-type or n-type) dopant. The semiconductor layer may receive an electrical signal applied from an external power source to emit light in a specific wavelength band. The light emitting element ED may include a first semiconductor layer 31, a second semiconductor layer 32, a light emitting layer 36, an electrode layer 37, and an insulating film 38.

The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, and 0≤x+y≤1). For example, the semiconductor material of the first semiconductor layer 31 may be one or more of AlGaInN, GaN, AlGaN, InGaN, AlN, and InN doped with an n-type dopant. The n-type dopant doped in the first semiconductor layer 31 may be Si, Ge, Sn, or the like.

The second semiconductor layer 32 may be disposed on the first semiconductor layer 31 with the light emitting layer 36 interposed therebetween. The second semiconductor layer 32 may be a p-type semiconductor, and may include a semiconductor material having a chemical formula of AlₓGa_{y}In_{1-x-y}N (0≤x≤1, 0≤y≤1, and 0≤x+y≤1). For example, the semiconductor material of the second semiconductor layer 32 may be one or more of AlGaInN, GaN, AlGaN, InGaN, AlN, and InN doped with a p-type dopant. The p-type dopant doped in the second semiconductor layer 32 may be Mg, Zn, Ca, Ba, or the like.

It is illustrated in the drawings that the first semiconductor layer 31 and the second semiconductor layer 32 are configured as a layer, but the disclosure is not limited thereto. The first semiconductor layer 31 and the second semiconductor layer 32 may further include a larger number of layers, for example, a clad layer or a tensile strain barrier reducing (TSBR) layer, depending on a material of the light emitting layer 36. For example, the light emitting element ED may further include another semiconductor layer disposed between the first semiconductor layer 31 and the light emitting layer 36 or between the second semiconductor layer 32 and the light emitting layer 36. The semiconductor layer disposed between the first semiconductor layer 31 and the light emitting layer 36 may be any one or more of AlGaInN, GaN, AlGaN, InGaN, AlN, and InN doped with the n-type dopant, and the semiconductor layer disposed between the second semiconductor layer 32 and the light emitting layer 36 may be any one or more of AlGaInN, GaN, AlGaN, InGaN, AlN, and InN doped with the p-type dopant.

The light emitting layer 36 may be disposed between the first semiconductor layer 31 and the second semiconductor layer 32. The light emitting layer 36 may include a material having a single or multiple quantum well structure. In case that the light emitting layer 36 includes the material having the multiple quantum well structure, the light emitting layer 36 may have a structure in which quantum layers and well layers are alternately stacked each other. The light emitting layer 36 may emit light by a combination of electron-hole pairs according to electrical signals applied through the first semiconductor layer 31 and the second semiconductor layer 32. The light emitting layer 36 may include a material such as AlGaN, AlGaInN, InGaN, or the like. In case that the light emitting layer 36 has the multiple quantum well structure, e.g., the structure in which the quantum layers and the well layers are alternately stacked each other, the quantum layers may include a material such as AlGaN or AlGaInN, and the well layers may include a material such as GaN or AlInN.

The light emitting layer 36 may also have a structure in which semiconductor materials having a large band gap energy and semiconductor materials having a small band gap energy are alternately stacked each other, and may also include other Group III to Group V semiconductor materials according to a wavelength band of emitted light. The light emitted by the light emitting layer 36 is not limited to the light in a blue wavelength band, and in some embodiments, the light emitting layer 36 may also emit light in red and green wavelength bands.

The electrode layer 37 may be an ohmic connection electrode. However, the disclosure is not limited thereto, and the electrode layer 37 may also be a Schottky connection electrode. The light emitting element ED may include at least one electrode layer 37. The light emitting element ED may include one or more electrode layers 37, but the disclosure is not limited thereto, and the electrode layer 37 may also be omitted.

The electrode layer 37 may decrease resistance between the light emitting element ED and the electrode or the connection electrode when the light emitting element ED is electrically connected to the electrode or the connection electrode in the display device 10. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO).

The insulating film 38 may be disposed to surround outer surfaces of the semiconductor layers and the electrode layer 37 described above. For example, the insulating film 38 may be disposed to surround at least an outer surface of the light emitting layer 36, but may be formed to expose ends of the light emitting element ED in a length direction. The insulating film 38 may also be formed so that an upper surface thereof is rounded in a cross-sectional view in an area thereof adjacent to at least one end of the light emitting element ED.

The insulating film 38 may include materials having insulating properties, for example, at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). It is illustrated in the drawing that the insulating film 38 is formed as a single layer, but the disclosure is not limited thereto, and in some embodiments, the insulating film 38 may also be formed in a multilayer structure in which layers are stacked each other.

The insulating film 38 may serve to protect the semiconductor layers and the electrode layer 37 of the light emitting element ED. The insulating film 38 may prevent an electrical short that may occur in the light emitting layer 36 in case that the light emitting element ED directly contacts an electrode through which an electrical signal is transmitted. The insulating film 38 may prevent a decrease in emission efficiency of the light emitting element ED.

An outer surface of the insulating film 38 may be surface-treated. The light emitting elements ED may be jetted and be aligned on the electrode in a state of being dispersed in an ink. Here, in order to maintain the light emitting elements ED in a state in which the light emitting elements ED are dispersed without being clustered with other adjacent light emitting elements ED in the ink, hydrophobic or hydrophilic treatment may be performed on a surface of the insulating film 38.

Hereinafter, processes for manufacturing the display device 10 described above will be described with reference to other drawings.

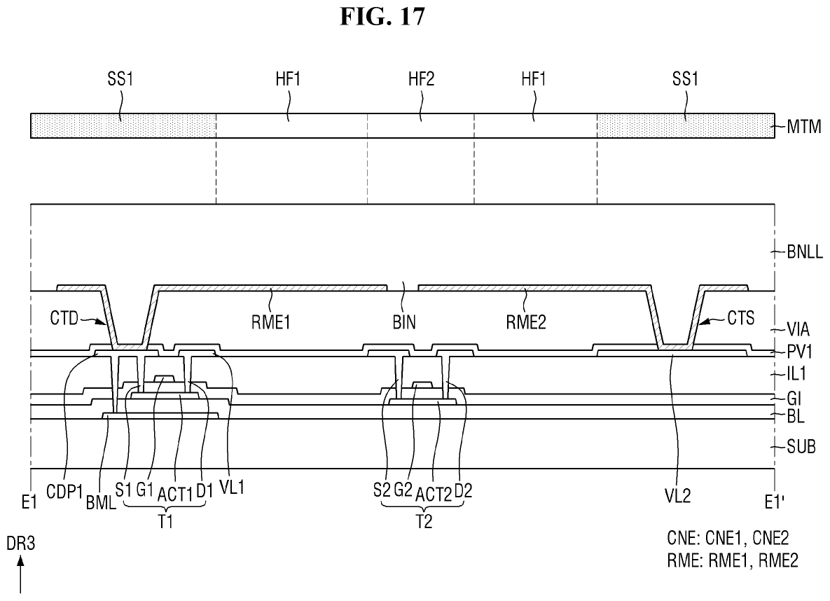

FIGS. 17 to 20 are schematic cross-sectional views illustrating a method for manufacturing a display device according to an embodiment for each process. A process for manufacturing the display device 10 illustrated in FIGS. 17 to 20 may correspond to the display device 10 of FIG. 5 described above.

First, referring to FIG. 17, a substrate SUB may be prepared, and a buffer layer BL, a semiconductor layer, first to third conductive layers, an interlayer insulating layer IL1, a passivation layer PV1, a via layer VIA, and electrodes RME1 and RME2 may be formed on the substrate SUB.

Each of the first to third conductive layers and the electrodes RME disposed on the substrate SUB may be formed by depositing a material constituting each layer, for example, a metal material, and performing a patterning process on such a material using a mask. Each of the buffer layer BL, the gate insulating layer GI, the interlayer insulating layer IL1, and the via layer VIA disposed on the substrate SUB may be formed by applying a material constituting each layer, for example, an insulating material, or performing a patterning process using a mask, if necessary. A description of the structure of the layers disposed on the substrate SUB may be the same as that described above, and thus a detailed description thereof will be omitted.

A bank material layer BNLL may be coated on the via layer VIA. The bank material layer BNLL may include, e.g., the above-described polyimide, fluorine-based liquid repellent additive, and/or photoactive compound. A solution coating method such as spin coating may be used for the bank material layer BNLL. A mask MTM may be aligned on the bank material layer BNLL. The mask MTM may be a half-tone mask or a multi-tone mask. The mask MTM may include a blocking area SSI by which light is blocked, and semi-transmissive areas HF1 and HF2 through which a transmission amount of light is adjusted. The semi-transmissive areas HF1 and HF2 may include a first semi-transmissive area HF1 and a second semi-transmissive area HF2 through which a larger amount of light is transmitted than the first semi-transmissive area HF1. The mask MTM may include a transmissive area through which light is completely transmitted, but the transmissive area is not illustrated in the drawing.

Among the areas of the mask MTM, the transmissive area may correspond to a portion where the bank material layer BNLL is to be completely removed, for example, an area corresponding to the separation portion ROP of the sub-area SA. The blocking area SSI may correspond to an area where the bank portion BNP of the bank layer BNL is to be formed. The first semi-transmissive area HF1 may correspond to an area where the partition portion BP of the bank layer BNL is to be formed, and the second semi-transmissive area HF2 may correspond to an area where the element portion BIN of the bank layer BNL is to be formed.

An exposure process of irradiating light toward the substrate SUB on the mask MTM may be performed. The light may be UV light. The light may be blocked in the blocking area SSI of the mask MTM. The amount of light may be adjusted and transmitted through the first semi-transmissive area HF1 of the mask MTM and may be irradiated to the bank material layer BNLL, and a larger amount of light than the first semi-transmissive area HF1 may be transmitted through the second semi-transmissive area HF2 and may be irradiated to the bank material layer BNLL. The bank material layer BNLL irradiated with light may be melted by a developing solution in a developing process to be described below. After the exposure process is performed, the mask MTM is removed.

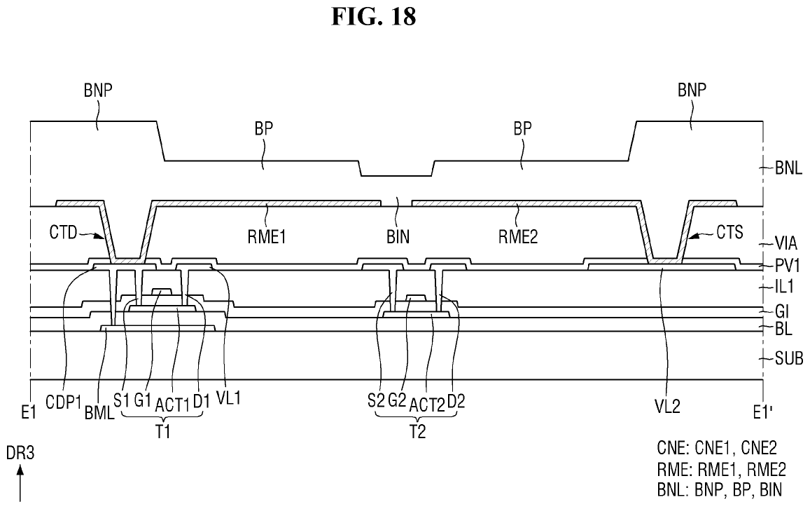

Referring to FIG. 18, a bank layer BNL may be formed by applying a developing solution to the bank material layer BNLL. The bank layer BNL may be completely removed from a portion corresponding to the transmission area of the mask MTM, and may be formed as a bank portion BNP in a portion corresponding to the blocking area SS1. In the bank layer BNL, the partition portion BP having a thickness smaller than that of the bank portion BNP may be formed at a portion corresponding to the first semi-transmissive area HF1 of the mask MTM, and the element portion BIN having a thickness smaller than that of the partition portion BP may be formed at a portion corresponding to the second semi-transmissive area HF2.

The exposure process using the mask MTM in FIGS. 17 and 18 may form the bank layer BNL as described in FIGS. 10 to 14. For example, in the soft bake process of the bank material layer BNLL, as the single molecule fluorine component present in the bank material layer BNLL gathers toward the surface, a large number of fluorine components may exist on the upper side of the bank material layer BNLL, and the fluorine components may decrease toward the lower side thereof. In the exposure process, in an area of the bank material layer BNLL to be formed as the bank portion BNP, a large number of fluorine components of the liquid repellent part may exist on the surface to exhibit liquid repellency. In the area of the bank material layer BNLL to be formed as the partition portion BP and the element portion BIN, the fluorine component may be insignificant, and —OH groups formed by combining the polymer resin and the photoactive compound may be exposed to the surface to exhibit a lyophilic property. As a result, the bank layer BNL formed to have a thick thickness may exhibit liquid repellency, and the bank layer BNL formed to have a thin thickness may exhibit a lyophilic property. Accordingly, the bank portion BNP of the bank layer BNL may exhibit liquid repellency, and the partition portion BP and the element portion BIN may exhibit a lyophilic property.

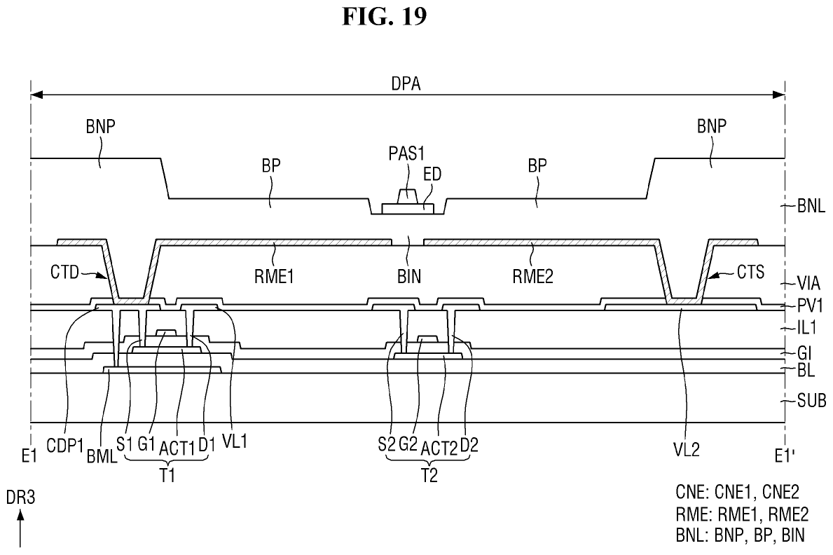

Referring to FIG. 19, light emitting elements ED mat be formed. The light emitting elements ED may be disposed on the electrode RME through an inkjet printing process. In case that the ink in which the light emitting elements ED are dispersed is jetted into the area surrounded by the bank layer BNL, and an electric signal is applied to the electrodes RME, the light emitting elements ED in the ink may be seated on the electrodes RME while positions and alignment directions thereof are changed. The ink may not spread to adjacent sub-pixels due to the bank portion BNP of the bank layer BNL, which exhibits liquid repellency, but may be collected in the partition portion BP and the element portion BIN, which exhibit a lyophilic property. The light emitting elements ED may be aligned by an electric field generated by an electrical signal applied to the electrode RME on the element portion BIN between the partition portions BP of the bank layer BNL. The light emitting element ED may be disposed such that a first end thereof is disposed on the first electrode RME1 and a second end thereof is disposed on the second electrode RME2. After the light emitting elements ED are aligned, a solvent of the ink may be removed.

A first insulating layer PAS1 may be formed. The first insulating layer PAS1 may be formed by depositing an inorganic insulating material on the substrate SUB on which the light emitting element ED and the bank layer BNL are formed and patterning the inorganic insulating material using a mask. First and second contact portions may be formed by partially etching the bank layer BNL during the patterning process on the first insulating layer PAS1.

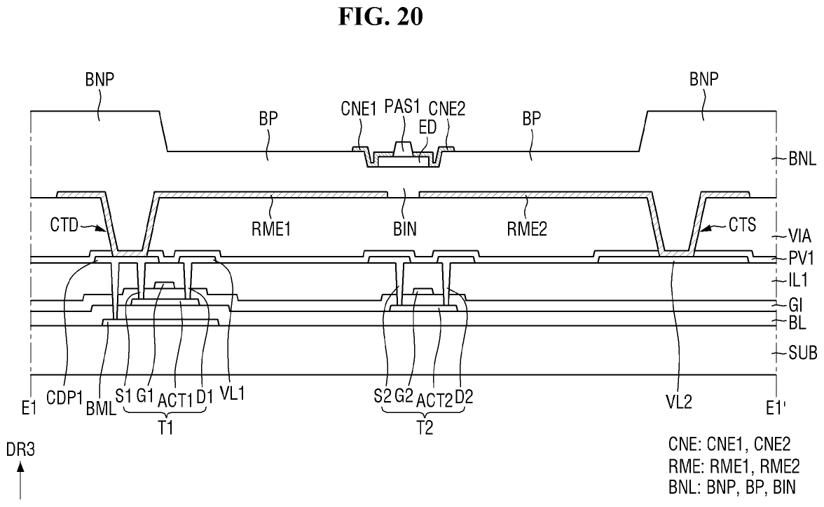

Referring to FIG. 20, a first connection electrode CNE1 and a second connection electrode CNE2 may be formed by stacking and patterning a connection electrode material layer on the light emitting element ED, the first insulating layer PAS1, and the bank layer BNL. Each of the first connection electrode CNE1 and the second connection electrode CNE2 may directly contact the light emitting element ED, and may directly contact the bank layer BNL and the first insulating layer PAS1. Accordingly, the display device 10 according to an embodiment may be manufactured.

As described above, in the method for manufacturing the display device 10 according to an embodiment, the bank portion BNP having liquid repellency, and the partition portion BP and the element portion BIN having a lyophilic property, of the bank layer BNL may be formed using a mask, thereby reducing the number of masks, reducing manufacturing costs, and improving productivity.

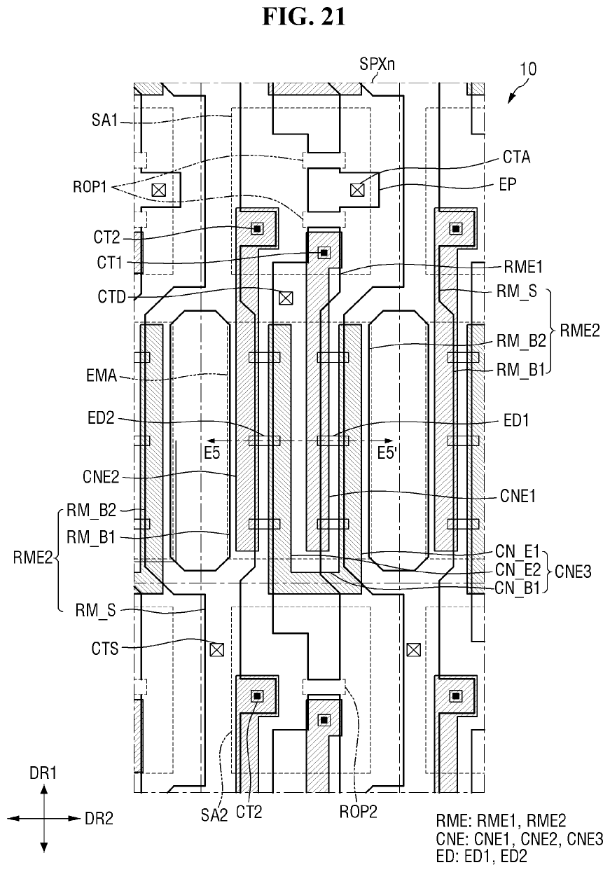

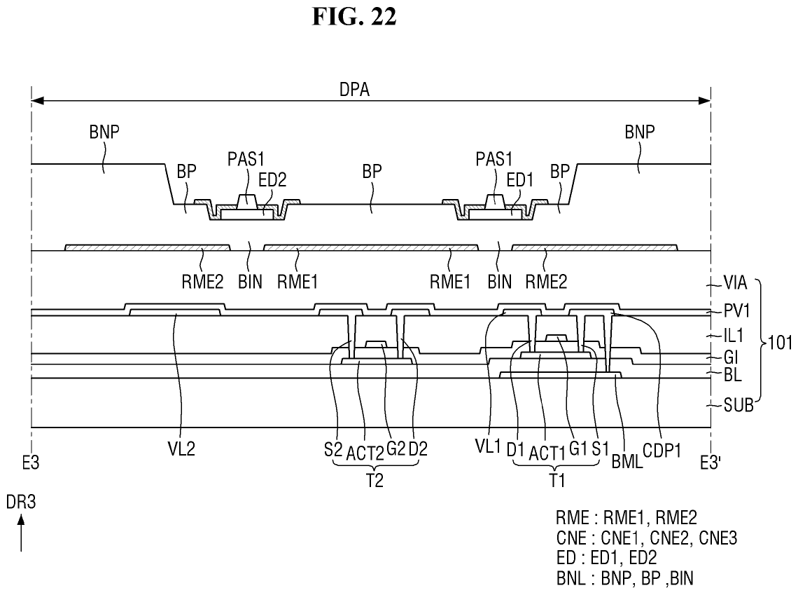

FIG. 21 is a schematic plan view illustrating a sub-pixel of a display device according to another embodiment. FIG. 22 is a schematic cross-sectional view taken along line E3-E3′ of FIG. 21.

FIG. 21 illustrates a planar arrangement of electrodes RME (RME1 and RME2), a bank layer BNL, light emitting elements ED (ED1 and ED2), and connection electrodes CNE (CNE1, CNE2, and CNE3) disposed in a sub-pixel SPXn of the display device 10. FIG. 22 illustrates a cross section crossing ends of the light emitting elements ED (EDI and ED2) disposed on different electrodes RME.

The display device 10 according to an embodiment may include a larger number of light emitting elements ED (ED1 and ED2) and connection electrodes CNE (CNE1, CNE2, and CNE3). The display device 10 according to the present embodiment may be different from the display device 10 according to the embodiment of FIG. 4 in that a larger number of electrodes and light emitting elements are included in each sub-pixel SPXn. Hereinafter, a description for contents overlapping those described above will be omitted, and contents different from those described above will be mainly described.

Referring to FIGS. 21 and 22, the electrodes RME may include the first electrode RME1 disposed at a central portion of each sub-pixel SPXn and the second electrode RME2 disposed across different sub-pixels SPXn. The first electrode RME1 and the second electrode RME2 may generally have a shape extending in the first direction DR1, but the shapes of portions thereof disposed in the light emitting area EMA may be different from each other.

The first electrode RME1 may be disposed at the center of the sub-pixel SPXn, and a portion of the first electrode RME1 disposed in the light emitting area EMA may be disposed to overlap the partition portion BP and the element portion BIN of the bank layer BNL. The first electrode RME1 may extend from the sub-area SA in the first direction DR1 and extend up to a sub-area SA of another sub-pixel SPXn.

The second electrode RME2 may include a portion extending in the first direction DR1 and portions branched in the vicinity of the light emitting area EMA. In an embodiment, the second electrode RME2 may include an electrode stem portion RM_S extending in the first direction DR1, and electrode branch portions RM_B1 and RM_B2 branched from the electrode stem portion RM_S, bent in the second direction DR2, and extending in the first direction DR1. The electrode stem portion RM_S may be disposed to overlap a portion of the bank portion BNP of the bank layer BNL extending in the first direction DR1, and may be disposed on a side of the sub-area SA in the second direction DR2. The electrode branch portions RM_B1 and RM_B2 may be branched from the electrode stem portion RM_S disposed on a portion extending in the first direction DR1 and a portion extending in the second direction DR2 of the bank portion BNP of the bank layer BNL, and may be bent to sides in the second direction DR2, respectively. The electrode branch portions RM_B1 and RM_B2 may be disposed to cross the light emitting area EMA in the first direction DR1, may be bent again, and may be integrated with the electrode stem portion RM_S to be connected to each other. For example, the electrode branch portions RM_B1 and RM_B2 of the second electrode RME2 may be branched from an upper side of the second electrode RME2 based on the light emitting area EMA of a sub-pixel SPXn and may be connected to each other again on a lower side of the second electrode RME2.

The second electrode RME2 may include a first electrode branch portion RM_B1 disposed on a left side of the first electrode RME1 and a second electrode branch portion RM_B2 disposed on a right side of the first electrode RME1. The electrode branch portions RM_B1 and RM_B2 included in a second electrode RME2 may be disposed in the light emitting area EMA of sub-pixels SPXn adjacent to each other in the second direction DR2, and the electrode branch portions RM_B1 and RM_B2 of the second electrodes RME2 different from each other may be disposed in a sub-pixel SPXn. The first electrode branch portion RM_B1 of the second electrode RME2 may be disposed on the left side of the first electrode RME1, and the second electrode branch portion RM_B2 of another second electrode RME2 may be disposed on the right side of the first electrode RME1. A width of the first electrode RME1 measured in the second direction DR2 may be greater than those of the electrode stem portion RM_S and the electrode branch portions RM_B1 and RM_B2 of the second electrode RME2.

The first electrode RME1 may contact the first conductive pattern of the third conductive layer through a first electrode contact hole CTD at a portion thereof overlapping a portion of the bank layer BNL extending in the second direction DR2. The second electrode RME2 may contact the second voltage line VL2 of the third conductive layer through the second electrode contact hole CTS in the electrode stem portion RM_S. The first electrode RME1 may be disposed so that a portion disposed in the sub-area SA overlaps the first contact portion CT1, and the second electrode RME2 may include a portion protruding from the electrode stem portion RM_S in the second direction DR2 and disposed in the sub-area SA and may overlap the second contact portion CT2 at the protruding portion.

The first electrode RME1 of the first electrode RME1 and the second electrode RME2 may be disposed up to separation portions ROP1 and ROP2 of the sub-area SA, while the second electrode RME2 may not be separated in the sub-area SA. A second electrode RME2 may include electrode stem portions RM_S and electrode branch portions RM_B1 and RM_B2 and may have a shape extending in the first direction DR1 and branched in the vicinity of the light emitting area EMA of each sub-pixel SPXn. The first electrode RME1 may be disposed between the separation portions ROP1 and ROP2 disposed in different sub-areas SA1 and SA2 of each sub-pixel SPXn and may be disposed across the light emitting area EMA.

According to an embodiment, the display device 10 may include a wiring connection electrode EP disposed in a first sub-area SA1 among the sub-areas SA1 and SA2 of each sub-pixel SPXn and disposed between the first electrodes RME1 of different sub-pixels SPXn. In the second sub-area SA2 of the sub-pixel SPXn, the wiring connection electrode EP may not be disposed, and the first electrodes RME1 of different sub-pixels SPXn adjacent to each other in the first direction DR1 may be spaced apart from each other. In a sub-pixel SPXn adjacent to the sub-pixel SPXn of FIG. 18 in the first direction DR1, the first sub-area SA1 in which the wiring connection electrode EP is disposed may be disposed on the upper side of the light emitting area EMA, and the second sub-area SA2 may be disposed on the lower side of the light emitting area EMA.

The first electrode RME1 may be spaced apart from the wiring connection electrode EP with the first separation portion ROP1 interposed therebetween in the first sub-area SA1. Two first separation portions ROP1 may be disposed in a first sub-area SA1, and the wiring connection electrode EP may be spaced apart from the first electrode RME1 disposed in the corresponding sub-pixel SPXn with the lower first separation portion ROP1 interposed therebetween and may be spaced apart from the first electrode RME1 disposed in another sub-pixel SPXn with the upper first separation portion ROP1 interposed therebetween. In the second sub-area SA2, a second separation portion ROP2 may be disposed, and different first electrodes RME1 may be spaced apart from each other in the first direction DR1.

In an embodiment, the wiring connection electrode EP may be connected to the first voltage line VL1 of the third conductive layer through a third electrode contact hole CTA penetrating through the via layer VIA. The first electrode RME1 may be formed in a state connected to the wiring connection electrode EP, and an electric signal applied to dispose the light emitting elements ED may be applied from the first voltage line VL1 to the first electrode RME1 through the wiring connection electrode EP. In the process of arranging the light emitting element ED, signals may be applied to the first voltage line VL1 and the second voltage line VL2, and may be transmitted to the first electrode RME1 and the second electrode RME2, respectively.

The second electrode contact hole CTS may be disposed in a portion of the bank portion BNP of the bank layer BNL surrounding the second sub-area SA2, and the third electrode contact hole CTA may be disposed in the first sub-area SA1. This may be because the second electrode contact hole CTS and the third electrode contact hole CTA expose the upper surfaces of the voltage lines VL1 and VL2 that are different from each other, respectively, so that a position of each electrode contact hole is determined accordingly.

The bank layer BNL may partition the light emitting area EMA and the sub-areas SA1 and SA2, similar to the bank layer BNL in the above-described embodiment. The bank layer BNL may include a bank portion BNP, a partition portion BP having a thickness different from that of the bank portion BNP, and element portions BIN having a thickness different from that of the bank portion BNP and the partition portion BP.

The element portions BIN of the bank layer BNL may be disposed in the light emitting area EMA of each sub-pixel SPXn. The element portions BIN may have shapes extending in the first direction DR1 and spaced apart from each other in the second direction DR2 and may be surrounded by the partition portion BP. The partition portion BP may be disposed in the light emitting area EMA of each sub-pixel SPXn. The partition portion BP may have a shape surrounding the element portions BIN. The partition portion BP may be an area other than the bank portion BNP and the element portions BIN. The light emitting elements ED may be disposed between the partition portions BP. The bank portion BNP of the bank layer BNL may include portions extending in the first direction DR1 and the second direction DR2, and may partition the light emitting area EMA and the sub-area SA of each sub-pixel SPXn.

The bank portion BNP of the bank layer BNL may have a greater thickness than the partition portion BP and the element portion BIN. The partition portion BP of the bank layer BNL may have a greater thickness than the element portion BIN. The element portion BIN of the bank layer BNL may have a smaller thickness than the partition portion BP and the bank portion BNP. An atomic ratio of fluorine on the surface of the bank portion BNP of the bank layer BNL may be greater than an atomic ratio of fluorine on the surfaces of the partition portion BP and the element portion BIN, and the surface may exhibit liquid repellency. The surface of the partition portion BP and the element portion BIN of the bank layer BNL may have a relatively low atomic ratio of fluorine, so that the surface may exhibit a lyophilic property.

The light emitting elements ED may be respectively disposed on the element portions BIN of the bank layer BNL and may be disposed on different electrodes RME. The light emitting elements ED may include a first light emitting element EDI having ends disposed on the first electrode RME1 and the second electrode branch portion RM_B2 of the second electrode RME2, and a second light emitting element ED2 having ends disposed on the first electrode RME1 and the first electrode branch portion RM_B1 of another second electrode RME2. The first light emitting elements EDI may be disposed on the right side of the first electrode RME1, and the second light emitting elements ED2 may be disposed on the left side of the first electrode RME1. The first light emitting elements EDI may be disposed on the first electrode RME1 and the second electrode RME2, and the second light emitting elements ED2 may be disposed on the first electrode RME1 and the second electrode RME2.

The connection electrodes CNE (CNE1, CNE2, and CNE3) may include a first connection electrode CNE1, a second connection electrode CNE2, and a third connection electrode CNE3.

The first connection electrode CNE1 may have a shape extending in the first direction DR1, and may be disposed on the first electrode RME1. A portion of the first connection electrode CNE1 disposed on the partition portion BP may overlap the first electrode RME1 and extend in the first direction DR1 to be disposed up to the first sub-area SA1 positioned on the upper side of the light emitting area EMA beyond the bank layer BNL. The first connection electrode CNE1 may contact the first electrode RME1 through the first contact portion CT1 in the first sub-area SA1.

The second connection electrode CNE2 may have a shape extending in the first direction DR1, and may be disposed on the second electrode RME2. A portion of the second connection electrode CNE2 disposed on the partition portion BP may overlap the second electrode RME2 and extend in the first direction DR1 to be disposed up to the first sub-area SA1 positioned on the upper side of the light emitting area EMA beyond the bank layer BNL. The second connection electrode CNE2 may contact the second electrode RME2 through the second contact portion CT2 in the first sub-area SA1.

In a sub-pixel SPXn adjacent to the sub-pixel SPXn of FIG. 21 in the first direction DR1, the first connection electrode CNE1 and the second connection electrode CNE2 may contact the first electrode RME1 and the second electrode RME2 through the contact portions CT1 and CT2 disposed in the second sub-area SA2, respectively.

The third connection electrode CNE3 may include extension portions CN_E1 and CN_E2 extending in the first direction DR1 and a first connection portion CN_B1 connecting the extension portions CN_E1 and CN_E2 to each other. The first extension portion CN_E1 may face the first connection electrode CNE1 in the light emitting area EMA and may be disposed on the second electrode branch portion RM_B2 of the second electrode RME2, and the second extension portion CN_E2 may face the second connection electrode CNE2 in the light emitting area EMA and may be disposed on the first electrode RME1. The first connection portion CN_B1 may extend in the second direction DR2 on the bank layer BNL disposed on the lower side of the light emitting area EMA to connect the first extension portion CN_E1 and the second extension portion CN_E2 to each other. The third connection electrode CNE3 may be disposed in the light emitting area EMA and on the bank layer BNL, and may not be directly connected to the electrode RME. The second electrode branch portion RM_B2 disposed on a lower side of the first extension portion CN_E1 may be electrically connected to the second voltage line VL2, but the second power voltage applied to the second electrode branch portion RM_B2 may not be transmitted to the third connection electrode CNE3.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a via layer disposed on a substrate;
a first electrode and a second electrode disposed on the via layer and spaced apart from each other;
a bank layer disposed on the first electrode and the second electrode;
light emitting elements disposed on the bank layer;
an insulating layer disposed on the light emitting elements; and
a first connection electrode and a second connection electrode spaced apart from each other on the bank layer and the light emitting elements, the first connection electrode being electrically connected to one end of the light emitting elements and the second connection electrode being electrically connected to another end of the light emitting elements, wherein
the bank layer includes an element portion overlapping the light emitting element, a partition portion surrounding the element portion, and a bank portion surrounding the partition portion, and
the bank layer includes fluorine, and an atomic ratio of fluorine on a surface of the bank portion is about 11% or more.

2. The display device of claim 1, wherein the bank portion, the partition portion, and the element portion of the bank layer have different thicknesses.

3. The display device of claim 1, wherein a thickness of the bank portion is greater than a thickness of the partition portion and a thickness of the element portion.

4. The display device of claim 3, wherein the thickness of the partition portion is greater than the thickness of the element portion.

5. The display device of claim 1, wherein a thickness of the partition portion is about 1.475 μm or more.

6. The display device of claim 1, wherein a thickness of the partition portion and a thickness of the element portion are about 1.438 μm or less.

7. The display device of claim 1, wherein the atomic ratio of fluorine on the surface of the bank portion is greater than an atomic ratio of fluorine on a surface of the partition portion and an atomic ratio of fluorine on a surface of the element portion.

8. The display device of claim 1, wherein the atomic ratio of fluorine on the surface of the bank portion is greater than an atomic ratio of fluorine at a center of the bank portion in a thickness direction.

9. The display device of claim 1, wherein the bank portion, the partition portion, and the element portion of the bank layer are integral with each other.

10. A display device comprising:
a via layer disposed on a substrate;
a first electrode and a second electrode disposed on the via layer and spaced apart from each other;
a bank layer disposed on the first electrode and the second electrode;
light emitting elements disposed on the bank layer;
an insulating layer disposed on the light emitting elements; and
a first connection electrode and a second connection electrode spaced apart from each other on the bank layer and the light emitting elements, the first connection electrode being electrically connected to one end of the light emitting elements and the second connection electrode being electrically connected to another end of the light emitting elements, wherein
the bank layer includes an element portion overlapping the light emitting element, a partition portion surrounding the element portion, and a bank portion surrounding the partition portion, and
the bank layer includes fluorine, and an atomic ratio of fluorine on a surface of each of the partition portion and the element portion is about 9.1% or less.

11. The display device of claim 10, wherein a thickness of the partition portion is about 1.475 μm or more.

12. The display device of claim 10, wherein a thickness of the partition portion and a thickness of the element portion are about 1.438 μm or less.

13. The display device of claim 10, wherein an atomic ratio of fluorine on a surface of the bank portion is greater than the atomic ratio of fluorine on the surface of the partition portion and the atomic ratio of fluorine on the surface of the element portion.

14. The display device of claim 10, wherein an atomic ratio of fluorine on a surface of the bank portion is greater than an atomic ratio of fluorine at a center of the bank portion in a thickness direction.

15. A method for manufacturing a display device, the method comprising:
forming a via layer on a substrate;
forming a first electrode and a second electrode spaced apart from each other on the via layer;
forming a bank layer including a bank portion, a partition portion, and an element portion having different thicknesses by applying a bank material layer on the first electrode and the second electrode and using a mask;
forming light emitting elements on the element portion of the bank layer;
forming an insulating layer on the light emitting elements; and
forming a first connection electrode and a second connection electrode spaced apart from each other on the light emitting elements, the first connection electrode being electrically connected to one end of the light emitting elements and the second connection electrode being electrically connected to another end of the light emitting elements.

16. The method of claim 15, wherein the bank material layer includes polyimide, a fluorine-based liquid repellent additive, and a photoactive compound.

17. The method of claim 15, wherein the mask includes a blocking area, a first semi-transmissive area, and a second semi-transmissive area through which a greater amount of light is transmitted than the first semi-transmissive area.

18. The method of claim 17, wherein
the bank material layer corresponding to the blocking area is formed as the bank portion,
the bank material layer corresponding to the first semi-transmissive area is formed as the partition portion, and
the bank material layer corresponding to the second semi-transmissive area is formed as the element portion.

19. The method of claim 15, wherein the forming of the bank layer includes:
collecting a fluorine component included in the bank material layer toward a surface by performing a soft bake process on the bank material layer;
performing an exposure process on the bank material layer through the mask;
developing the bank material layer; and
curing the bank material layer.

20. The method of claim 19, wherein an atomic ratio of fluorine on a surface of the bank portion is greater than an atomic ratio of fluorine on a surface of the partition portion and an atomic ratio of fluorine on a surface of the element portion.

21. The method of claim 19, wherein an atomic ratio of fluorine on a surface of the bank portion is greater than an atomic ratio of fluorine at a center of the bank portion in a thickness direction.

22. The method of claim 15, wherein
the thickness of the bank portion is greater than the thickness of the partition portion, and
the thickness of the partition portion is greater than the thickness of the element portion.

23. The method of claim 15, wherein the thickness of the partition portion is formed to be about 1.475 μm or more.

24. The method of claim 15, wherein the thickness of the partition portion and the thickness of the element portion are formed to be about 1.438 μm or less.
